(19) United States
(12) Patent Application Publication
(10) Pub. No.: US 2026/0206249 A1
(43) Pub. Date: Jul. 16, 2026

(54) SEMICONDUCTOR DEVICE, SEMICONDUCTOR DEVICE MANUFACTURING METHOD, AND ELECTRONIC APPARATUS

(71) Applicant: 1FINITY Inc., Kawasaki-shi (JP)

(72) Inventor: Shirou OZAKI, Yamato (JP)

(73) Assignee: 1FINITY Inc., Kawasaki-shi (JP)

(21) Appl. No.: 19/443,873

(22) Filed: Jan. 8, 2026

(30) Foreign Application Priority Data
Jan. 14, 2025 (JP) 2025-004890

(51) Int. Cl. H10D 30/47; H10D 30/01

(52) U.S. Cl. CPC H10D 30/475; H10D 30/015

(57) ABSTRACT

A semiconductor device includes a semiconductor layer, a gate electrode provided on a first surface of the semiconductor layer, a first electrode provided on the first surface of the semiconductor layer and separated from the gate electrode, a first oxide film provided between the gate electrode and the first electrode on the first surface of the semiconductor layer and apart from the first electrode.

### CROSS-REFERENCE TO RELATED APPLICATION

This application is based upon and claims the benefit of priority of the prior Japanese Patent Application No. 2025-004890, filed on January 14, 2025, the entire contents of which are incorporated herein by reference.

### FIELD

The present embodiments relate to a semiconductor device, a semiconductor device manufacturing method, and an electronic apparatus.

### BACKGROUND

For example, there is known a semiconductor device including a gate electrode provided on a channel region of an oxide semiconductor film, and including conductive films provided in openings formed in an insulating film such as a nitride on a source region and a drain region of the oxide semiconductor film (Japanese Laid-Open Patent Publication No. 2020-205423). In addition, for example, there is known a semiconductor device in which a protective film of an insulating film is provided between a gate electrode and a drain electrode on a second nitride semiconductor layer that forms a two-dimensional electron gas between the second nitride semiconductor layer and a first nitride semiconductor layer, and an oxide layer is provided between the gate electrode and a source electrode (International Publication Pamphlet No. WO2022/264191).

### SUMMARY

In one aspect, there is provided a semiconductor device including: a semiconductor layer; a gate electrode provided on a first surface of the semiconductor layer; a first electrode provided on the first surface of the semiconductor layer and separated from the gate electrode; and a first oxide film provided between the gate electrode and the first electrode on the first surface of the semiconductor layer and apart from the first electrode.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a diagram illustrating an example of a semiconductor device according to a first embodiment;

FIGS. 2A and 2B are diagrams illustrating configuration examples of an oxide film of the semiconductor device according to the first embodiment;

FIGS. 3A and 3B are diagrams illustrating an example of an effect of the oxide film in the semiconductor device according to the first embodiment;

FIG. 4 is a diagram illustrating an example of a semiconductor device according to a second embodiment;

FIG. 5 is a diagram illustrating another example of the semiconductor device according to the second embodiment;

FIGS. 6A and 6B are diagrams illustrating examples of a semiconductor device according to a third embodiment;

FIG. 7 is a diagram illustrating another example of the semiconductor device according to the third embodiment;

FIGS. 8A and 8B are diagrams illustrating examples of a semiconductor device according to a fourth embodiment;

FIG. 9 is a diagram illustrating another example of the semiconductor device according to the fourth embodiment;

FIGS. 10A and 10B are views (part 1) illustrating an example of a semiconductor device manufacturing method according to a fifth embodiment;

FIGS. 11A and 11B are views (part 2) illustrating the example of the semiconductor device manufacturing method according to the fifth embodiment;

FIGS. 12A and 12B are views (part 1) illustrating an example of a semiconductor device manufacturing method according to a sixth embodiment;

FIGS. 13A and 13B are views (part 2) illustrating the example of the semiconductor device manufacturing method according to the sixth embodiment;

FIG. 14 is a diagram illustrating an example of a semiconductor package according to a seventh embodiment;

FIG. 15 is a diagram illustrating an example of a power factor correction circuit according to an eighth embodiment;

FIG. 16 is a diagram illustrating an example of a power supply device according to a ninth embodiment; and

FIG. 17 is a diagram illustrating an example of an amplifier according to a tenth embodiment.

### DESCRIPTION OF EMBODIMENTS

In a semiconductor device, if an oxide film is provided between a gate electrode and an electrode such as a source electrode or a drain electrode so as to be in contact with the electrode, the electrode may be oxidized by O (oxygen) in the oxide film, and the resistance of the electrode may increase, thereby deteriorating the performance of the semiconductor device.

### FIRST EMBODIMENT

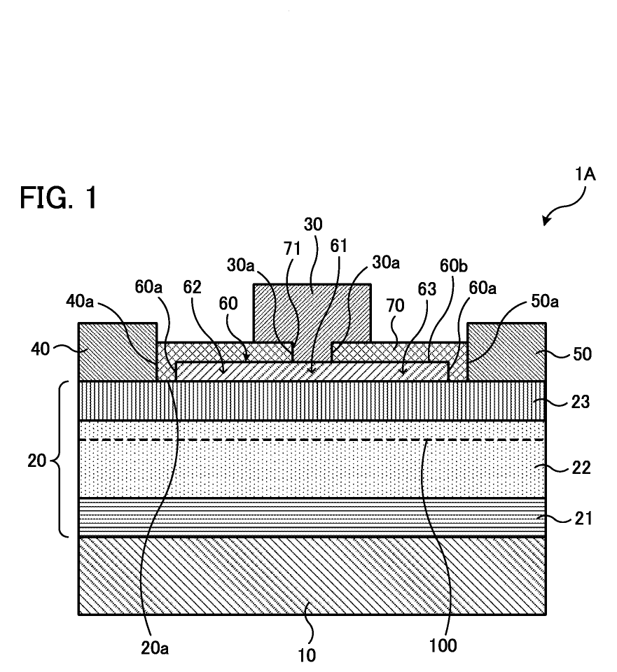

FIG. 1 is a diagram illustrating an example of a semiconductor device according to a first embodiment. FIG. 1 schematically illustrates a cross-sectional view of a main part of an example of the semiconductor device according to the first embodiment.

A semiconductor device 1A illustrated in FIG. 1 is a high electron mobility transistor (HEMT). The semiconductor device 1A includes a substrate 10, a semiconductor layer 20, a gate electrode 30, a source electrode 40, a drain electrode 50, an oxide film 60, and a nitride film 70.

One of various substrates is used as the substrate 10. For example, one of various substrates such as sapphire, Si (silicon), SiC (silicon carbide), GaN (gallium nitride), AlN (aluminum nitride), InP (indium phosphide), GaAs (gallium arsenide), and diamond may be used as the substrate 10. The substrate 10 may have a single-layer structure of one type of substrate, or may have a stacked structure of two or more types of substrates.

The semiconductor layer 20 includes, for example, a buffer layer 21, a channel layer 22, and an electron supply layer 23. The buffer layer 21 is provided on one surface of the substrate 10. The channel layer 22 is provided on a surface of the buffer layer 21, the surface being opposite to the one surface. The electron supply layer 23 is provided on a surface of the channel layer 22, the surface being opposite to the surface facing the buffer layer 21. The channel layer 22 is also referred to as an “electron transit layer”. The electron supply layer 23 is also referred to as a “barrier layer”.

For example, a compound semiconductor is used for the buffer layer 21, the channel layer 22, and the electron supply layer 23. The compound semiconductor used for the buffer layer 21, the channel layer 22, and the electron supply layer 23 is selected according to the form of the semiconductor device 1A, the type of the substrate 10, and the like.

For example, when the semiconductor device 1A is a so-called GaN-based HEMT, a substrate made of sapphire, Si, SiC, GaN, AlN, or the like is used as the substrate 10. Compound semiconductors of the respective layers such as the buffer layer 21, the channel layer 22, and the electron supply layer 23 are grown on the substrate 10 by metal organic chemical vapor deposition (MOCVD) or the like. For example, AlN or the like is used for the buffer layer 21. For example, GaN or the like is used for the channel layer 22. For example, AlGaN (aluminum gallium nitride) or the like is used for the electron supply layer 23.

Note that a semiconductor device functioning as a HEMT or a transistor included therein in which the semiconductor layer 20 including the channel layer 22 using GaN or the like and the electron supply layer 23 using AlGaN or the like is provided on the predetermined substrate 10 is also referred to as a “GaN-based HEMT”. The individual compound semiconductor used in the GaN-based HEMT is also referred to as a “GaN-based semiconductor”.

For example, when the semiconductor device 1A is a so-called InP-based HEMT, a substrate of InP or the like is used as the substrate 10. Compound semiconductors of the respective layers such as the buffer layer 21, the channel layer 22, and the electron supply layer 23 are grown on the substrate 10 by using an MOCVD method or the like. For example, InAlAs (indium aluminum arsenide) or the like is used for the buffer layer 21. For example, InGaAs (indium gallium arsenide) or the like is used for the channel layer 22. For example, InAlAs or the like is used for the electron supply layer 23.

Note that a semiconductor device functioning as a HEMT or a transistor included therein in which the semiconductor layer 20 including the channel layer 22 using InGaAs or the like and the electron supply layer 23 using InAlAs or the like is provided on the substrate 10 made of InP or the like is also referred to as an “InP-based HEMT”. The individual compound semiconductor used in the InP-based HEMT is also referred to as an “InP-based semiconductor”.

For example, when the semiconductor device 1A is a so-called GaAs-based HEMT, a substrate of GaAs or the like is used as the substrate 10. Compound semiconductors of the respective layers such as the buffer layer 21, the channel layer 22, and the electron supply layer 23 are grown on the substrate 10 by using an MOCVD method or the like. For example, AlGaAs (aluminum gallium arsenide) or the like is used for the buffer layer 21. For example, GaAs or the like is used for the channel layer 22. For example, AlGaAs or the like is used for the electron supply layer 23.

Note that a semiconductor device functioning as a HEMT or a transistor included therein in which the semiconductor layer 20 including the channel layer 22 using GaAs or the like and the electron supply layer 23 using AlGaAs or the like is provided on the substrate 10 of GaAs or the like is also referred to as a “GaAs-based HEMT”. The individual compound semiconductor used in the GaAs-based HEMT is also referred to as a “GaAs-based semiconductor”.

In the semiconductor layer 20, a compound semiconductor different from the compound semiconductor used for the channel layer 22 and having a larger band gap than the compound semiconductor used for the channel layer 22 is used for the electron supply layer 23. The compound semiconductor used for the channel layer 22 is also referred to as a “first compound semiconductor”, and the compound semiconductor used for the electron supply layer 23 is also referred to as a “second compound semiconductor”. In the semiconductor layer 20, due to spontaneous polarization of the electron supply layer 23 and piezoelectric polarization generated in the electron supply layer 23 by strain caused by a lattice constant difference from the channel layer 22, a two-dimensional electron gas (2DEG) region 100 is created in the channel layer 22.

The gate electrode 30, the source electrode 40, and the drain electrode 50 are provided on a surface of the semiconductor layer 20, that is, on a surface 20a of the semiconductor layer 20, the surface 20a being opposite to the substrate 10. The surface 20a of the semiconductor layer 20 is also referred to as a “first surface”.

The source electrode 40 and the drain electrode 50 are separated from each other. A metal such as Ti (titanium), Ta (tantalum), Pt (platinum), or Au (gold) is used for the source electrode 40 and the drain electrode 50. One kind or two or more kinds of metals may be used for the source electrode 40 and the drain electrode 50. The source electrode 40 and the drain electrode 50 are provided to function as ohmic electrodes. A regrown layer using a compound semiconductor containing an n-type impurity may be provided as a contact layer in a portion of the semiconductor layer 20 to which the source electrode 40 and the drain electrode 50 are connected.

The gate electrode 30 is provided between the source electrode 40 and the drain electrode 50 so as to be separated therefrom. A metal such as Ni (nickel), Ti, Ta, Pt, or Au is used for the gate electrode 30. One kind or two or more kinds of metals may be used for the gate electrode 30. The gate electrode 30 is provided on the surface 20a of the semiconductor layer 20 via a part of the oxide film 60, that is, via a first portion 61. The gate electrode 30 has a MIS (Metal Insulator Semiconductor) gate structure. The first portion 61 of the oxide film 60 interposed between the gate electrode 30 and the semiconductor layer 20, that is, the first portion 61 immediately below the gate electrode 30, functions as a gate insulating film.

In the semiconductor device 1A, the oxide film 60 has the first portion 61 functioning as a gate insulating film between the gate electrode 30 and the semiconductor layer 20. The oxide film 60 further includes a second portion 62 provided between the gate electrode 30 and the source electrode 40, and further includes a third portion 63 provided between the gate electrode 30 and the drain electrode 50. The second portion 62 and the third portion 63 of the oxide film 60 are provided continuously with the first portion 61 functioning as a gate insulating film.

In the semiconductor device 1A, the oxide film 60 is provided on the surface 20a of the semiconductor layer 20 so as to be separated from the source electrode 40 and the drain electrode 50. That is, a side surface 60a of the oxide film 60, the side surface 60a being at the second portion 62, and a side surface 40a of the source electrode 40 facing the side surface 60a, are provided so as not to be in contact with each other. A side surface 60a of the oxide film 60, the side surface 60a being at the third portion 63, and a side surface 50a of the drain electrode 50 facing the side surface 60a, are provided so as not to be in contact with each other.

The oxide film 60 contains Al (aluminum). The oxide film 60 may further contain Hf (hafnium), Si, or the like, in addition to Al. The oxide film 60 is, for example, an amorphous oxide film. When the oxide film 60 is crystalline, a current leakage path may be formed by a crystal grain boundary inside the oxide film 60. On the other hand, when the oxide film 60 is amorphous, the formation of the current leakage path is suppressed, and the insulating property is enhanced.

In the semiconductor device 1A, the source electrode 40 is also referred to as a “first electrode”, the drain electrode 50 is also referred to as a “second electrode”, the first portion 61 of the oxide film 60 is also referred to as a “gate insulating film”, the second portion 62 is also referred to as a “first oxide film”, and the third portion 63 of the oxide film 60 is also referred to as a “second oxide film”. Alternatively, the drain electrode 50 is also referred to as a “first electrode”, the source electrode 40 is also referred to as a “second electrode”, the first portion 61 of the oxide film 60 is also referred to as a “gate insulating film”, the third portion 63 is also referred to as a “first oxide film”, and the second portion 62 is also referred to as a “second oxide film”.

The nitride film 70 is provided so as to cover the side surface 60a and an upper surface 60b of the oxide film 60 (except for the portion to which the gate electrode 30 is connected). Part of the nitride film 70 is provided in portions of the surface 20a of the semiconductor layer 20, the portions not covered with the oxide film 60. That is, part of the nitride film 70 is provided between the side surface 40a of the source electrode 40 and the side surface 60a of the oxide film 60, the side surface 60a facing the side surface 40a, and between the side surface 50a of the drain electrode 50 and the side surface 60a of the oxide film 60, the side surface 60a facing the side surface 50a. As a result, the source electrode 40 and the oxide film 60 are disposed to be separated from each other, and are isolated from each other via the nitride film 70 provided therebetween. In addition, the drain electrode 50 and the oxide film 60 are disposed to be separated from each other, and are isolated from each other via the nitride film 70 provided therebetween. One of the portion of the nitride film 70 provided between the source electrode 40 and the oxide film 60 and the portion of the nitride film 70 provided between the drain electrode 50 and the oxide film 60 is also referred to as a “first nitride film”, and the other is also referred to as a “second nitride film”.

The nitride film 70 has an opening 71 leading to the oxide film 60. The gate electrode 30 is provided on part of the nitride film 70 and in the opening 71. The nitride film 70 has a function of protecting the surface 20a of the semiconductor layer 20. The nitride film 70 is also referred to as a “protective film”, a “passivation film”, or the like.

The nitride film 70 contains Si. The nitride film 70 may further contain O, C (carbon), or the like, in addition to Si. The nitride film 70 is, for example, an amorphous nitride film. When the nitride film 70 is amorphous, the formation of a current leakage path is suppressed, and the insulating property is enhanced.

During operation of the semiconductor device 1A, for example, a voltage is applied such that the drain electrode 50 has a higher potential than the source electrode 40, and a predetermined voltage is applied to the gate electrode 30. The electric field effect by the voltage applied to the gate electrode 30 controls the amount of charge in the 2DEG region 100 of the channel layer 22 immediately below the gate electrode 30, and controls the magnitude of the output drain current flowing between the source electrode 40 and the drain electrode 50. For example, the transistor function of the semiconductor device 1A is achieved in this manner.

As described above, in the semiconductor device 1A, the oxide film 60 is provided apart from the source electrode 40 and the drain electrode 50.

Here, if the oxide film 60 is provided so as to be in contact with the source electrode 40 and the drain electrode 50, O in the oxide film 60 may diffuse into the source electrode 40 and the drain electrode 50 due to heat applied during the manufacture of the semiconductor device 1A in which the oxide film 60 is formed as described above or during the subsequent operation. When O in the oxide film 60 diffuses into the source electrode 40 and the drain electrode 50, the source electrode 40 and the drain electrode 50 are oxidized, and the resistance thereof may increase.

In contrast, in the semiconductor device 1A, the oxide film 60 is provided apart from the source electrode 40 and the drain electrode 50. Therefore, even when heat is applied during the manufacturing or operation, the diffusion of O in the oxide film 60 into the source electrode 40 and the drain electrode 50 is suppressed. Therefore, the oxidation of the source electrode 40 and the drain electrode 50 due to the diffusion of O in the oxide film 60 is suppressed, and an increase in resistance of the source electrode 40 and the drain electrode 50 due to the oxidation is suppressed. Thus, the high-performance semiconductor device 1A is obtained.

The oxide film 60 of the semiconductor device 1A will be further described.

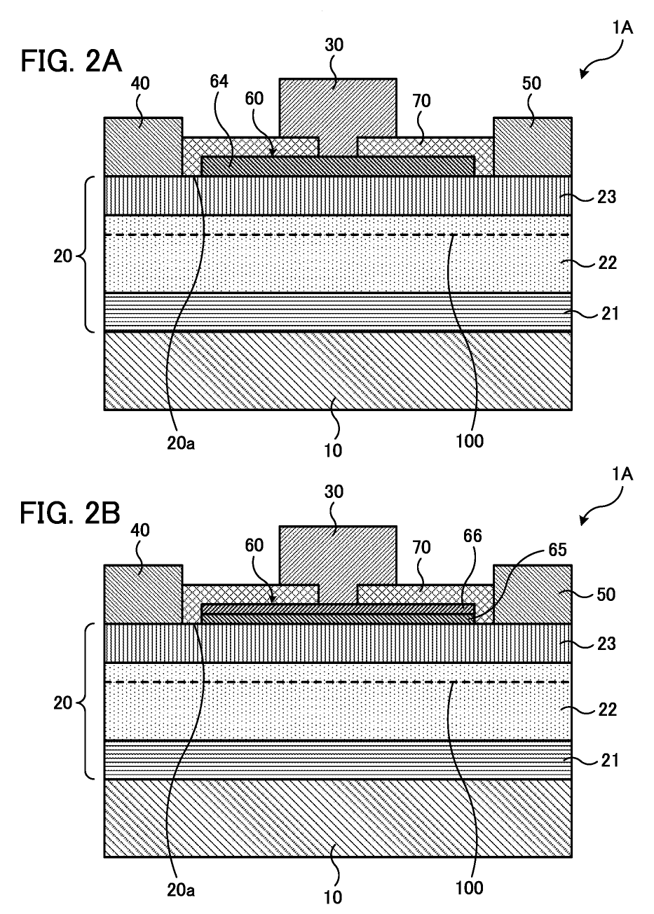

FIGS. 2A and 2B are diagrams illustrating configuration examples of the oxide film of the semiconductor device according to the first embodiment. FIG. 2A schematically illustrates a cross-sectional view of a main part of an example of the semiconductor device according to the first embodiment, which has an oxide film having a single-layer structure. FIG. 2B schematically illustrates a cross-sectional view of a main part of another example of the semiconductor device according to the first embodiment, which has an oxide film having a stacked structure.

As illustrated in FIG. 2A, an oxide film 64 having a single-layer structure may be provided as the oxide film 60 of the semiconductor device 1A. For example, as the oxide film 60 having a single-layer structure, an oxide film containing Al, for example, aluminum oxide (AlO), is provided.

As the oxide film 60 of the semiconductor device 1A, as illustrated in FIG. 2B, an oxide film having a stacked structure including a first layer 65 as a lower layer and a second layer 66 as an upper layer stacked thereon may be provided. As the first layer 65, an oxide film containing Al, for example, AlO, is provided. As the second layer 66, an oxide film containing Hf, for example, HfO (hafnium oxide), is provided. As the second layer 66, an oxide film containing Hf and Al, an oxide film containing Hf and Si, or an oxide film containing Hf, Al, and Si may be provided. For example, other than HfO, HfAlO (hafnium aluminate), HfSiO (hafnium silicate), HfAlSiO (hafnium aluminosilicate), or the like may be provided as the second layer 66.

Although FIG. 2B illustrates the oxide film 60 having a two-layer structure including the first layer 65 and the second layer 66, the number of stacked layers of the oxide film 60 is not limited to two. In the semiconductor device 1A, an oxide film having a stacked structure of three or more layers containing two or more kinds of oxide film materials may be provided as the oxide film 60.

As described above, the oxide film 60 of the semiconductor device 1A may have a single-layer structure according to the example in FIG. 2A, or may have a stacked structure according to the example in FIG. 2B.

Here, configuration examples of the oxide film 60 have been described. Similarly, the nitride film 70 may have a single-layer structure or a stacked-layer structure. The nitride film 70 may contain Si or may further contain O, C, or the like. For example, SiN (silicon nitride) may be provided as the nitride film 70. Alternatively, SiON (silicon oxynitride), SiCN (silicon carbonitride), SiOCN (silicon oxycarbonitride), or the like may be provided as the nitride film 70. For example, such a nitride film material may have a single-layer structure or a stacked-layer structure and be provided as the nitride film 70 of the semiconductor device 1A.

Next, an effect of the oxide film 60 in the semiconductor device 1A will be described.

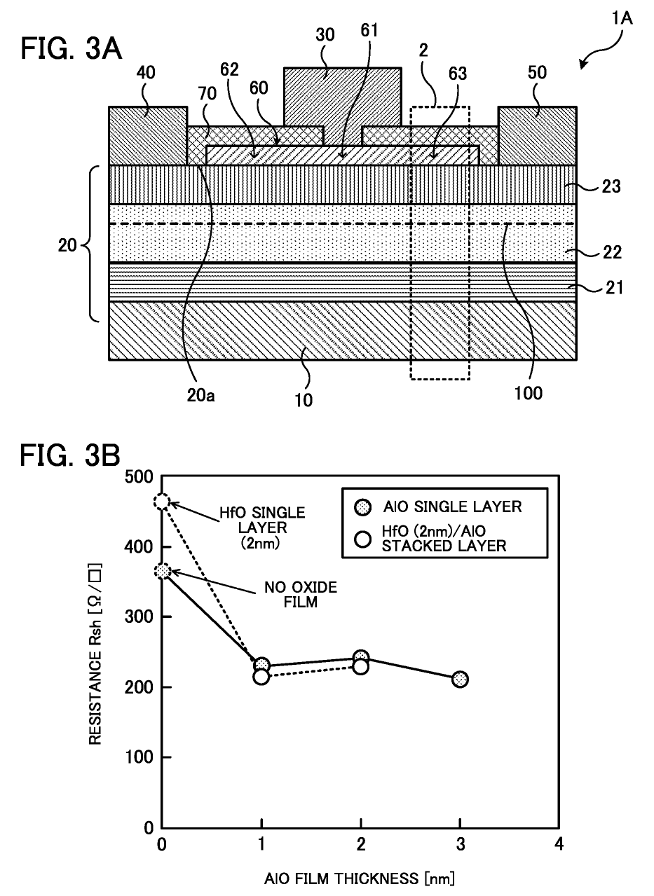

FIGS. 3A and 3B are diagrams illustrating an example of an effect of the oxide film in the semiconductor device according to the first embodiment. FIG. 3A schematically illustrates a cross-sectional view of a main part of an example of the semiconductor device according to the first embodiment. FIG. 3B illustrates an example of the relationship between the thickness of the oxide film and the resistance of an access region of the semiconductor device according to the first embodiment.

For example, when the oxide film 60 such as AlO is provided on the semiconductor layer 20, defects at the interface between the semiconductor layer 20 and the oxide film 60 are reduced. By reducing these defects at the interface between the semiconductor layer 20 and the oxide film 60, electrons of carriers flowing through the channel layer 22 during operation of the semiconductor device 1A are prevented from being captured by the defects. As a result, the resistance of the channel layer 22 is reduced, and an increase in current and an increase in output of the semiconductor device 1A are achieved. In order to further improve the performance of the semiconductor device 1A, it is effective to increase the dielectric constant (high-k) of the oxide film 60. As one of the high dielectric constant films, an oxide film containing Hf, such as HfO, is known.

As illustrated in FIG. 3A, in the semiconductor device 1A, the first portion 61 of the oxide film 60 is provided immediately below the gate electrode 30. The second portion 62 of the oxide film 60 is provided in the access region between the gate electrode 30 and the source electrode 40. The third portion 63 of the oxide film 60 is provided in the access region between the gate electrode 30 and the drain electrode 50. As an example, the resistance (sheet resistance) of a part of the access region 2 between the gate electrode 30 and the drain electrode 50 was evaluated when the form of the oxide film 60 provided therein was changed. FIG. 3B illustrates the results. In FIG. 3B, the horizontal axis represents the AlO film thickness [nm], and the vertical axis represents the resistance Rsh [Ω/□].

FIG. 3B indicates, when an AlO film having a single layer structure and having a film thickness of 1nm, 2 nm, and 3nm is provided as the oxide film 60 (“AlO single layer” in FIG. 3B), the resistance Rsh of the access region 2 is less than that when the oxide film 60 is not provided (“no oxide film” in FIG. 3B).

On the other hand, FIG. 3B indicates that, when an HfO film having a single-layer structure and having a film thickness of 2 nm is provided as the oxide film 60 (“HfO single layer (2 nm)” in the drawing), the resistance Rsh of the access region 2 is relatively high. However, when an oxide film having a stacked structure in which an HfO film having a film thickness of 2 nm is stacked on an AlO film having a film thickness of 1 nm is provided as the oxide film 60 (“HfO (2 nm)/AlO stacked layer” in the drawing), the resistance Rsh of the access region 2 is less than that when the AlO film having a single layer structure and having a film thickness of 1 nm and 2 nm is provided. The same applies to when an oxide film having a stacked structure in which an HfO film having a film thickness of 2 nm is stacked on an AlO film having a film thickness of 2 nm is provided as the oxide film 60 (“HfO (2 nm)/AlO stacked layer” in the drawing).

Thus, when an AlO film having a single-layer structure is provided as the oxide film 60, the resistance Rsh of the access region 2 is made less than that when the oxide film 60 is not provided. Further, when an oxide film having a stacked structure in which HfO is stacked on AlO is provided as the oxide film 60, the resistance Rsh of the access region 2 is reduced more effectively. By providing AlO as the oxide film 60 on the semiconductor layer 20, the defects at the interface between the semiconductor layer 20 and the oxide film 60 are reduced, and the resistance of the channel layer 22 is reduced. Further, by providing an oxide film in which HfO is stacked on AlO as the oxide film 60, higher performance is achieved by the increased high-k.

Although HfO has been exemplified as the oxide film containing Hf, the same effect is obtained by using HfAlO, HfSiO, HfAlSiO, or the like.

Incidentally, impurities tend to remain in an oxide film such as an HfO film containing Hf. Therefore, the oxide film such as an HfO film is preferably subjected to annealing at a temperature higher than 300°C, which is a general film formation temperature of an oxide film, for example, high-temperature annealing at 350°C or higher, after film formation.

Here, as described above, when the oxide film 60 is provided so as to be in contact with the source electrode 40 and the drain electrode 50, oxidation of the source electrode 40 and the drain electrode 50 and an increase in resistance due to the oxidation may occur due to diffusion of O in the oxide film 60. The diffusion of O in the oxide film 60 could also occur when an oxide film such as an AlO film containing Al is provided as the oxide film 60, and could also occur when an oxide film in which an oxide film such as an HfO film containing Hf is stacked on an oxide film such as an AlO film containing Al is provided. In the case where an oxide film in which an oxide film such as an HfO film is stacked on an oxide film such as an AlO film is provided as the oxide film 60, when the high-temperature annealing as described above is performed after the formation of the HfO film or the like, the diffusion of O in the oxide film 60 is more likely to occur. Therefore, when the oxide film 60 is in contact with the source electrode 40 and the drain electrode 50, oxidation of the source electrode 40 and the drain electrode 50 and an increase in resistance due to the oxidation are likely to occur.

In contrast, in the semiconductor device 1A, the oxide film 60 is not in contact with the source electrode 40 and the drain electrode 50, and is provided apart from the source electrode 40 and the drain electrode 50. Therefore, even when heat is applied during manufacturing or operation of the semiconductor device 1A, the diffusion of O in the oxide film 60 into the source electrode 40 and the drain electrode 50 is suppressed.

As described above, according to the semiconductor device 1A, by providing the oxide film 60 between the gate electrode 30 and the source electrode 40 and between the gate electrode 30 and the drain electrode 50, the resistance of the channel layer 22 is reduced, and a large current and a high output are achieved. Furthermore, since the oxide film 60 is provided apart from the source electrode 40 and the drain electrode 50, the diffusion of O in the oxide film 60 into the source electrode 40 and the drain electrode 50 is suppressed. Since the diffusion of O in the oxide film 60 is suppressed, the oxidation of the source electrode 40 and the drain electrode 50 is suppressed, and an increase in resistance of the source electrode 40 and the drain electrode 50 due to the oxidation is suppressed. Thus, the high-performance semiconductor device 1A is obtained.

In the semiconductor device 1A, each of the source electrode 40 and the drain electrode 50 may include a portion provided in an active region functioning as a transistor and a portion provided in an element isolation region defining the active region. In this case, for example, the oxide film 60 may be provided so as to be separated from any of the portions of the source electrode 40 and the drain electrode 50, the portions being provided in the active region and the portions being provided in the element isolation region. Alternatively, the oxide film 60 may be provided so as to be separated from the portions of the source electrode 40 and the drain electrode 50, the portions being provided in the active region, while being in contact with the portions provided in the element isolation region. Even in such a case, since the oxide film 60 is separated from the portions of the source electrode 40 and the drain electrode 50, the portions being provided in the active region, the diffusion of O in the active region functioning as a transistor and the oxidation and the increase in resistance due to the diffusion are suppressed.

### SECOND EMBODIMENT

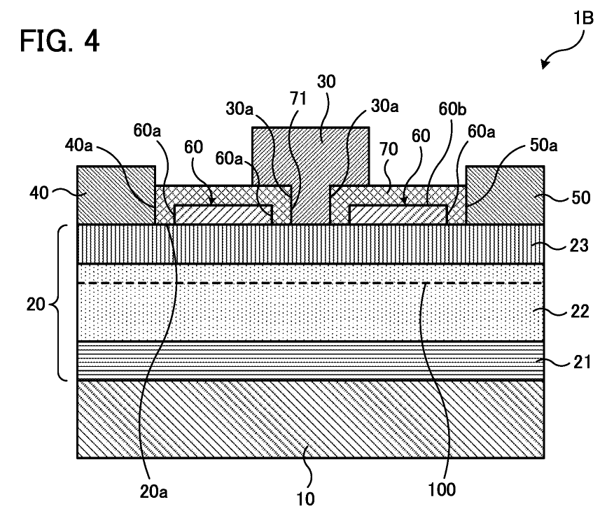

FIG. 4 is a diagram illustrating an example of a semiconductor device according to a second embodiment. FIG. 4 schematically illustrates a cross-sectional view of a main part of an example of the semiconductor device according to the second embodiment.

A semiconductor device 1B illustrated in FIG. 4 is an example of a HEMT. The semiconductor device 1B may be a HEMT made of various materials, such as a GaN-based HEMT, an InP-based HEMT, and a GaAs-based HEMT.

The semiconductor device 1B includes a gate electrode 30 functioning as a Schottky electrode on a surface 20a of a semiconductor layer 20. In the semiconductor device 1B, one oxide film 60 is provided between the gate electrode 30 and a source electrode 40, and another oxide film 60 is provided between the gate electrode 30 and a drain electrode 50 on the surface 20a of the semiconductor layer 20. In the semiconductor device 1B, the one oxide film 60 (side surfaces 60a thereof) between the gate electrode 30 and the source electrode 40 is provided apart from the gate electrode 30 (a side surface 30a thereof) and the source electrode 40 (the side surface 40a thereof). In the semiconductor device 1B, the another oxide film 60 (side surfaces 60a thereof) between the gate electrode 30 and the drain electrode 50 is provided apart from the gate electrode 30 (a side surface 30a thereof) and the drain electrode 50 (a side surface 50a thereof). In the semiconductor device 1B, part of the nitride film 70 covering the oxide films 60 (the side surfaces 60a and upper surfaces 60b thereof) is provided between the oxide films 60 and the gate electrode 30, between the one oxide film 60 and the source electrode 40, and between the another oxide film 60 and the drain electrode 50.

The semiconductor device 1B is different from the semiconductor device 1A (FIG. 1, etc.) described in the first embodiment in that the semiconductor device 1B has the above-described configuration.

In the semiconductor device 1B, the source electrode 40 is also referred to as a “first electrode”, the drain electrode 50 is also referred to as a “second electrode”, the oxide film 60 between the gate electrode 30 and the source electrode 40 is also referred to as a “first oxide film”, and the oxide film 60 between the gate electrode 30 and the drain electrode 50 is also referred to as a “second oxide film”. Alternatively, the drain electrode 50 is also referred to as a “first electrode”, the source electrode 40 is also referred to as a “second electrode”, the oxide film 60 between the gate electrode 30 and the drain electrode 50 is also referred to as a “first oxide film”, and the oxide film 60 between the gate electrode 30 and the source electrode 40 is also referred to as a “second oxide film”.

As the oxide films 60 of the semiconductor device 1B, the oxide film 60 described with the semiconductor device 1A is used. That is, as the oxide films 60, for example, an oxide film having a single-layer structure such as an AlO film containing Al is provided. Alternatively, as the oxide films 60, an oxide film having a stacked structure including an oxide film such as an AlO film containing Al and an oxide film such as an HfO film containing Hf stacked thereon is provided.

In the semiconductor device 1B, one oxide film 60 is provided between the gate electrode 30 and the source electrode 40, and another oxide film 60 is provided between the gate electrode 30 and the drain electrode 50, whereby the resistance of a channel layer 22 is reduced, and a large current and a high output are achieved. Furthermore, since these oxide films 60 are provided apart from the source electrode 40 and the drain electrode 50, diffusion of O in the oxide films 60 into the source electrode 40 and the drain electrode 50 is suppressed. Since the diffusion of O in the oxide film 60 into the source electrode 40 and the drain electrode 50 is suppressed, the oxidation of the source electrode 40 and the drain electrode 50 is suppressed, and an increase in resistance of the source electrode 40 and the drain electrode 50 due to the oxidation is suppressed.

In addition, in the semiconductor device 1B, since the oxide films 60 are provided apart from the gate electrode 30, the diffusion of O in the oxide films 60 into the gate electrode 30 is suppressed. Since the diffusion of O in the oxide films 60 into the gate electrode 30 is suppressed, the oxidation of the gate electrode 30 is suppressed, and an increase in resistance of the gate electrode 30 due to the oxidation is suppressed. Further, a short channel effect due to the oxidation of the side surfaces 30a of the gate electrode 30 is suppressed.

Thus, the high-performance semiconductor device 1B is obtained.

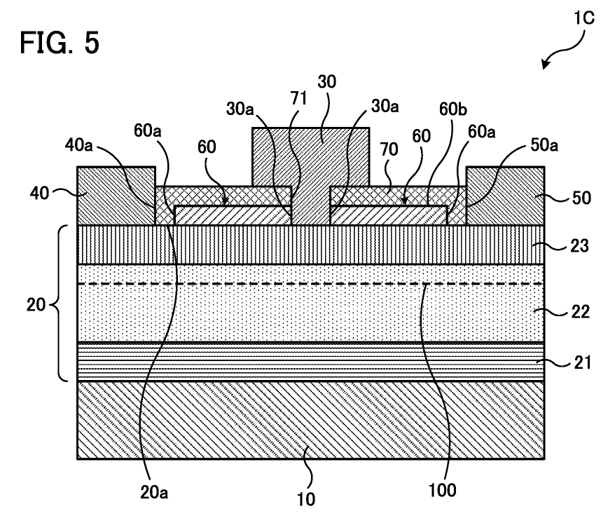

FIG. 5 is a diagram illustrating another example of the semiconductor device according to the second embodiment. FIG. 5 schematically illustrates a cross-sectional view of a main part of another example of the semiconductor device according to the second embodiment.

A semiconductor device 1C illustrated in FIG. 5 is different from the semiconductor device 1B (FIG. 4) in that one oxide film 60 provided between the gate electrode 30 and the source electrode 40 and another oxide film 60 between the gate electrode 30 and the drain electrode 50 are provided so as to be in contact with the gate electrode 30 (the side surfaces 30a thereof).

In the semiconductor device 1C, the source electrode 40 is also referred to as a “first electrode”, the drain electrode 50 is also referred to as a “second electrode”, the oxide film 60 between the gate electrode 30 and the source electrode 40 is also referred to as a “first oxide film”, and the oxide film 60 between the gate electrode 30 and the drain electrode 50 is also referred to as a “second oxide film”. Alternatively, the drain electrode 50 is also referred to as a “first electrode”, the source electrode 40 is also referred to as a “second electrode”, the oxide film 60 between the gate electrode 30 and the drain electrode 50 is also referred to as a “first oxide film”, and the oxide film 60 between the gate electrode 30 and the source electrode 40 is also referred to as a “second oxide film”.

For example, when a material that is hardly oxidized by O in the oxide films 60 is used for the gate electrode 30, the configuration of the semiconductor device 1C illustrated in FIG. 5 may be employed. Alternatively, even when the side surfaces 30a of the gate electrode 30 are oxidized by O in the oxide films 60, in the case where deterioration of the transistor performance due to the short channel effect is suppressed and a predetermined transistor performance is maintained, the configuration of the semiconductor device 1C illustrated in FIG. 5 may be employed.

Also in the semiconductor device 1C, one oxide film 60 is provided between the gate electrode 30 and the source electrode 40, and another oxide film 60 is provided between the gate electrode 30 and the drain electrode 50, whereby the resistance of the channel layer 22 is reduced, and a large current and a high output are achieved. Furthermore, since the oxide films 60 are provided apart from the source electrode 40 and the drain electrode 50, the oxidation of the source electrode 40 and the drain electrode 50 due to the diffusion of O in the oxide film 60 is suppressed, and an increase in resistance of the source electrode 40 and the drain electrode 50 due to the oxidation is suppressed. Thus, the high-performance semiconductor device 1C is obtained.

### THIRD EMBODIMENT

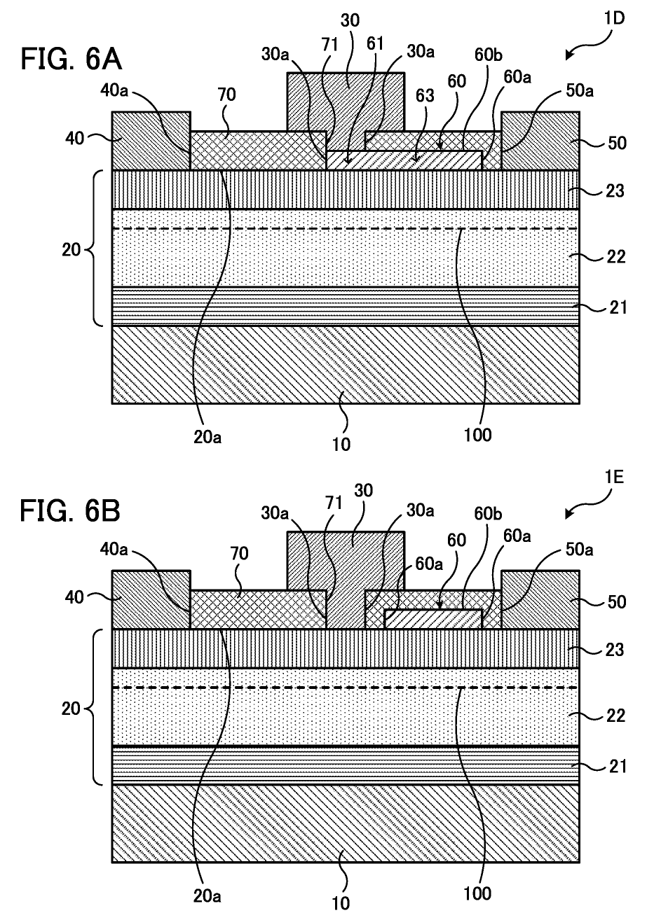

FIGS. 6A and 6B are diagrams illustrating examples of a semiconductor device according to a third embodiment. FIG. 6A schematically illustrates a cross-sectional view of a main part of a first example of the semiconductor device according to the third embodiment. FIG. 6B schematically illustrates a cross-sectional view of a main part of a second example of the semiconductor device according to the third embodiment.

A semiconductor device 1D illustrated in FIG. 6A is an example of a HEMT. The semiconductor device 1D is, for example, a GaN-based HEMT.

In the semiconductor device 1D, an oxide film 60 is provided between a surface 20a of a semiconductor layer 20 and a gate electrode 30 and between the gate electrode 30 and a drain electrode 50 on the surface 20a of the semiconductor layer 20. In the semiconductor device 1D, a first portion 61 of the oxide film 60 between the surface 20a of the semiconductor layer 20 and the gate electrode 30 functions as a gate insulating film. In the semiconductor device 1D, a third portion 63 (a side surface 60a thereof) of the oxide film 60 between the gate electrode 30 and the drain electrode 50 is provided apart from the drain electrode 50 (a side surface 50a thereof). In the semiconductor device 1D, the third portion 63 of the oxide film 60 is provided continuously with the first portion 61. In the semiconductor device 1D, part of a nitride film 70 covering the oxide film 60 (the side surface 60a and an upper surface 60b thereof) is provided between the oxide film 60 and the drain electrode 50. In the semiconductor device 1D, the oxide film 60 is not provided between the gate electrode 30 and a source electrode 40 on the surface 20a of the semiconductor layer 20. The portion between the gate electrode 30 and the source electrode 40 is covered with a nitride film 70.

The semiconductor device 1D is different from the semiconductor device 1A (FIG. 1, etc.) described in the first embodiment in that the semiconductor device 1D has the above-described configuration.

In the semiconductor device 1D, the drain electrode 50 is also referred to as a “first electrode”, the first portion 61 of the oxide film 60 is also referred to as a “gate insulating film”, and the third portion 63 is also referred to as a “first oxide film”.

For the oxide film 60 of the semiconductor device 1D, the oxide film 60 as described with the semiconductor device 1A is used. That is, as the oxide film 60, for example, an oxide film having a single-layer structure such as an AlO film containing Al is provided. Alternatively, as the oxide film 60, an oxide film having a stacked structure including an oxide film such as an AlO film containing Al and an oxide film such as an HfO film containing Hf stacked thereon is provided.

In the GaN-based HEMT, the reduction of the resistance of the drain-side access region is effective for increasing the current and the output of the HEMT. To this end, an oxide film such as an AlO film or an oxide film obtained by stacking an AlO film or the like and an HfO film or the like may be provided on the surface of the semiconductor layer in the drain-side access region. In this way, the resistance of the drain-side access region is reduced based on the findings illustrated in FIGS. 3A and 3B.

In the semiconductor device 1D, by providing the oxide film 60 between the gate electrode 30 and the drain electrode 50, the resistance of the access region of a channel layer 22 between the gate electrode 30 and the drain electrode 50 is reduced. As a result, an increase in current and an increase in output of the semiconductor device 1D are achieved. Further, since the oxide film 60 is provided apart from the drain electrode 50, the oxidation of the drain electrode 50 due to the diffusion of O in the oxide film 60 is suppressed, and an increase in resistance of the drain electrode 50 due to the oxidation is suppressed. Thus, the high-performance semiconductor device 1D is obtained.

A semiconductor device 1E illustrated in FIG. 6B is an example of a HEMT. The semiconductor device 1E is, for example, a GaN-based HEMT.

The semiconductor device 1E includes a gate electrode 30 functioning as a Schottky electrode on a surface 20a of a semiconductor layer 20. In the semiconductor device 1E, an oxide film 60 is provided between the gate electrode 30 and a drain electrode 50 on the surface 20a of the semiconductor layer 20. In the semiconductor device 1E, the oxide film 60 (side surfaces 60a thereof) is provided apart from the gate electrode 30 (a side surface 30a thereof) and the drain electrode 50 (a side surface 50a thereof). In the semiconductor device 1E, part of a nitride film 70 covering the oxide film 60 (the side surfaces 60a and an upper surface 60b thereof) is provided between the oxide film 60 and the gate electrode 30 and between the oxide film 60 and the drain electrode 50. In the semiconductor device 1E, the oxide film 60 is not provided between the surface 20a of the semiconductor layer 20 and the gate electrode 30 and between the gate electrode 30 and the source electrode 40 on the surface 20a of the semiconductor layer 20. The portion between the gate electrode 30 and the source electrode 40 is covered with a nitride film 70.

The semiconductor device 1E is different from the semiconductor device 1B (FIG. 4) described in the second embodiment in that the semiconductor device 1E has the above-described configuration.

In the semiconductor device 1E, the drain electrode 50 is also referred to as a “first electrode”, and the oxide film 60 between the gate electrode 30 and the drain electrode 50 is also referred to as a “first oxide film”.

The oxide film 60 as described above is used for the oxide film 60 of the semiconductor device 1E. That is, as the oxide film 60, for example, an oxide film having a single-layer structure such as an AlO film containing Al is provided. Alternatively, as the oxide film 60, an oxide film having a stacked structure including an oxide film such as an AlO film containing Al and an oxide film such as an HfO film containing Hf stacked thereon is provided.

Also in the semiconductor device 1E including the GaN-based HEMT having the Schottky gate structure, the resistance of the access region of a channel layer 22 between the gate electrode 30 and the drain electrode 50 is reduced by providing the oxide film 60 between the gate electrode 30 and the drain electrode 50. As a result, an increase in current and an increase in output of the semiconductor device 1E are achieved. Further, since the oxide film 60 is provided apart from the drain electrode 50, the oxidation of the drain electrode 50 due to the diffusion of O in the oxide film 60 is suppressed, and an increase in resistance of the drain electrode 50 due to the oxidation is suppressed. Thus, the high-performance semiconductor device 1E is obtained.

Here, the semiconductor device 1E is illustrated in which the oxide film 60 between the gate electrode 30 and the drain electrode 50 is provided so as to be separated from the gate electrode 30. Alternatively, the oxide film 60 between the gate electrode 30 and the drain electrode 50 may be provided so as to be in contact with the gate electrode 30 (a side surface 30a thereof), as in the example of the semiconductor device 1C (FIG. 5) described in the second embodiment.

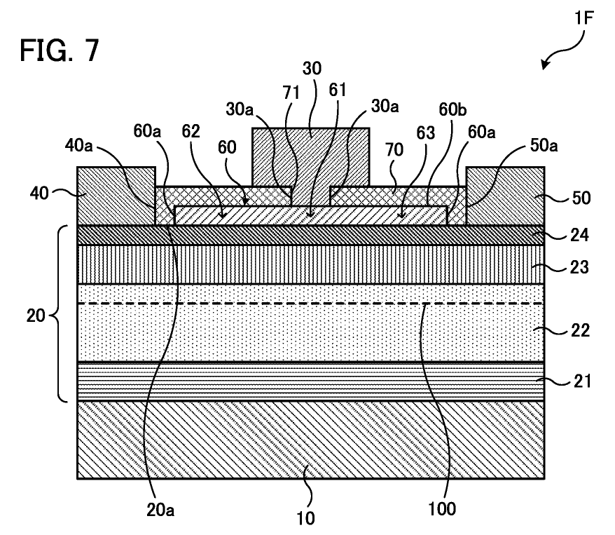

FIG. 7 is a diagram illustrating another example of the semiconductor device according to the third embodiment. FIG. 7 schematically illustrates a cross-sectional view of a main part of a third example of the semiconductor device according to the third embodiment.

A semiconductor device 1F illustrated in FIG. 7 is an example of a HEMT. The semiconductor device 1F is, for example, a GaN-based HEMT.

In the semiconductor device 1F, a semiconductor layer 20 includes a cap layer 24. The cap layer 24 is provided on a surface of an electron supply layer 23, the surface being opposite to a channel layer 22. A gate electrode 30, a source electrode 40, a drain electrode 50, an oxide film 60, and nitride films 70 are provided on a surface 20a of the semiconductor layer 20, the surface being is the front surface of the cap layer 24, as in the semiconductor device 1A (FIG. 1, etc.) described in the first embodiment.

The cap layer 24 has a function of protecting the electron supply layer 23. The cap layer 24 may be selectively provided in a region directly below the gate electrode 30 on the electron supply layer 23. For example, a GaN-based semiconductor such as doped (p-type or n-type) or non-doped GaN is used for the cap layer 24. The doping of the cap layer 24 may be selectively performed on a predetermined region such as a region immediately below the gate electrode 30 or a region between the gate electrode 30 and the source electrode 40 or the drain electrode 50. The cap layer 24 may have a function of modulating the electron concentration of a 2DEG region 100 of the channel layer 22 below the gate electrode 30 by doping. Alternatively, the cap layer 24 may have a function of modulating the electron concentration of the 2DEG region 100 of the channel layer 22 between the gate electrode 30 and the source electrode 40 or the drain electrode 50 by doping.

The source electrode 40 and the drain electrode 50 may be provided on the cap layer 24 as illustrated in FIG. 7, or may be provided through the cap layer 24.

Also in the semiconductor device 1F including the semiconductor layer 20 including the cap layer 24, the same effect as that of the semiconductor device 1A described in the first embodiment is obtained by the oxide film 60 provided on the surface 20a so as to be separated from the source electrode 40 and the drain electrode 50.

The semiconductor device 1F may have a Schottky gate structure in which the gate electrode 30 penetrates the oxide film 60 and reaches the semiconductor layer 20. In this case, the oxide film 60 may be provided so as not to be in contact with the gate electrode 30, or may be provided so as to be in contact with the gate electrode 30.

As in the example of the semiconductor device 1D (FIG. 6A), the semiconductor device 1F may have a configuration in which the oxide film 60 is provided between the gate electrode 30 and the semiconductor layer 20 and between the gate electrode 30 and the drain electrode 50, and is not provided between the gate electrode 30 and the source electrode 40.

As in the example of the semiconductor device 1E (FIG. 6B), the semiconductor device 1F may have a configuration in which the oxide film 60 is provided between the gate electrode 30 and the drain electrode 50 and is not provided between the gate electrode 30 and the semiconductor layer 20 and between the gate electrode 30 and the source electrode 40. In this case, the oxide film 60 may be provided so as not to be in contact with the gate electrode 30, or may be provided so as to be in contact with the gate electrode 30.

### FOURTH EMBODIMENT

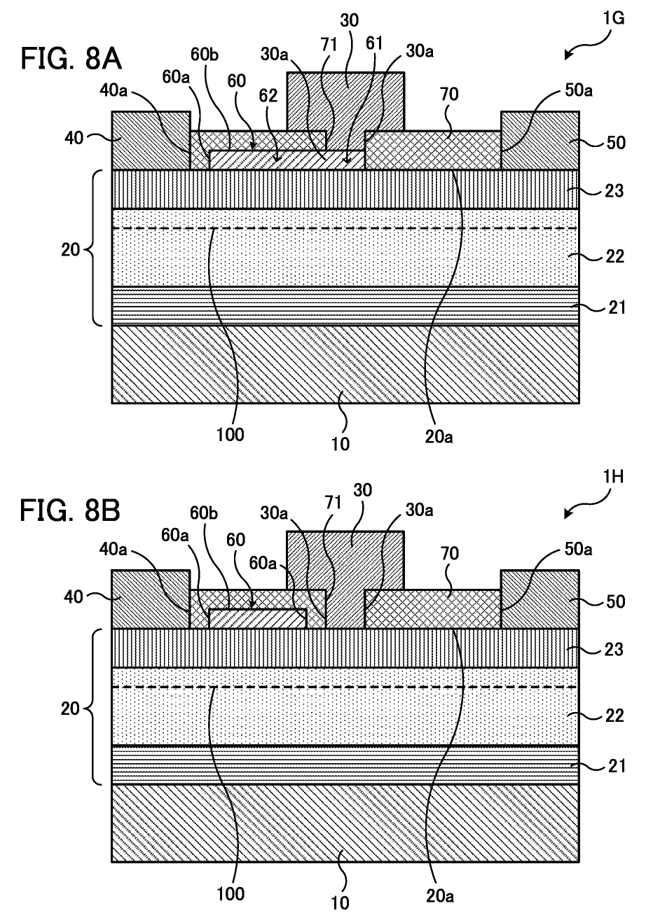

FIGS. 8A and 8B are diagrams illustrating examples of a semiconductor device according to a fourth embodiment. FIG. 8A schematically illustrates a cross-sectional view of a main part of a first example of the semiconductor device according to the fourth embodiment. FIG. 8B schematically illustrates a cross-sectional view of a main part of a second example of the semiconductor device according to the fourth embodiment.

A semiconductor device 1G illustrated in FIG. 8A is an example of a HEMT. The semiconductor device 1G is, for example, an InP-based HEMT.

In the semiconductor device 1G, the oxide film 60 is provided between a surface 20a of a semiconductor layer 20 and a gate electrode 30 and between the gate electrode 30 and a source electrode 40 on the surface 20a of the semiconductor layer 20. In the semiconductor device 1G, a first portion 61 of the oxide film 60, the first portion 61 being between the surface 20a of the semiconductor layer 20 and the gate electrode 30, functions as a gate insulating film. In the semiconductor device 1G, a second portion 62 (a side surface 60a thereof) of the oxide film 60, the second portion 62 being between the gate electrode 30 and the source electrode 40, is provided apart from the source electrode 40 (a side surface 40a thereof). In the semiconductor device 1G, the second portion 62 of the oxide film 60 is provided continuously with the first portion 61. In the semiconductor device 1G, part of the nitride film 70 covering the oxide film 60 (the side surface 60a and an upper surface 60b thereof) is provided between the oxide film 60 and the source electrode 40. In the semiconductor device 1G, the oxide film 60 is not provided between the gate electrode 30 and a drain electrode 50 on the surface 20a of the semiconductor layer 20. The portion between the gate electrode 30 and the drain electrode 50 is covered with a nitride film 70.

The semiconductor device 1G is different from the semiconductor device 1A (FIG. 1, etc.) described in the first embodiment in that the semiconductor device 1G has the above-described configuration.

In the semiconductor device 1G, the source electrode 40 is also referred to as a “first electrode”, the first portion 61 of the oxide film 60 is also referred to as a “gate insulating film”, and the second portion 62 is also referred to as a “first oxide film”.

The oxide film 60 as described with the semiconductor device 1A is used for the oxide film 60 of the semiconductor device 1G. That is, as the oxide film 60, for example, an oxide film having a single-layer structure such as an AlO film containing Al is provided. Alternatively, as the oxide film 60, an oxide film having a stacked structure including an oxide film such as an AlO film containing Al and an oxide film such as an HfO film containing Hf stacked thereon is provided.

In the InP-based HEMT, a reduction in the resistance of the source-side access region is effective for increasing the current and the output of the HEMT while suppressing an increase in the electric field of the drain-side access region. For this purpose, an oxide film such as an AlO film, for example, an oxide film such as an AlO film having oxygen vacancies (or oxygen defects), is provided on the surface 20a of the semiconductor layer 20 in the source-side access region. In this way, the conduction band of the junction between a channel layer 22 and an electron supply layer 23 in the source-side access region is lowered, and the electron density in a 2DEG region 100 is increased.

In the semiconductor device 1G, by providing the oxide film 60 between the gate electrode 30 and the source electrode 40, the resistance of the access region of the channel layer 22 between the gate electrode 30 and the source electrode 40 is reduced. As a result, an increase in current and an increase in output of the semiconductor device 1G are achieved. Further, since the oxide film 60 is provided apart from the source electrode 40, the oxidation of the source electrode 40 due to the diffusion of O in the oxide film 60 is suppressed, and an increase in resistance of the source electrode 40 due to the oxidation is suppressed. Thus, the high-performance semiconductor device 1G is obtained.

A semiconductor device 1H illustrated in FIG. 8B is an example of a HEMT. The semiconductor device 1H is, for example, an InP-based HEMT.

The semiconductor device 1H includes a gate electrode 30 functioning as a Schottky electrode on the surface 20a of a semiconductor layer 20. In the semiconductor device 1H, an oxide film 60 is provided between the gate electrode 30 and a source electrode 40 on the surface 20a of the semiconductor layer 20. In the semiconductor device 1H, the oxide film 60 (side surfaces 60a thereof) is provided apart from the gate electrode 30 (a side surface 30a thereof) and the source electrode 40 (a side surface 40a thereof). In the semiconductor device 1H, part of a nitride film 70 covering the oxide film 60 (the side surfaces 60a and an upper surface 60b thereof) is provided between the oxide film 60 and the gate electrode 30 and between the oxide film 60 and the source electrode 40. In the semiconductor device 1H, the oxide film 60 is not provided between the surface 20a of the semiconductor layer 20 and the gate electrode 30 and between the gate electrode 30 and a drain electrode 50 on the surface 20a of the semiconductor layer 20. The portion between the gate electrode 30 and the drain electrode 50 is covered with a nitride film 70.

The semiconductor device 1H is different from the semiconductor device 1B (FIG. 4) described in the second embodiment in that the semiconductor device 1H has the above-described configuration.

In the semiconductor device 1H, the source electrode 40 is also referred to as a “first electrode”, and the oxide film 60 between the gate electrode 30 and the source electrode 40 is also referred to as a “first oxide film”.

The oxide film 60 as described above is used for the oxide film 60 of the semiconductor device 1H. That is, as the oxide film 60, for example, an oxide film having a single-layer structure such as an AlO film containing Al is provided. Alternatively, as the oxide film 60, an oxide film having a stacked structure including an oxide film such as an AlO film containing Al and an oxide film such as an HfO film containing Hf stacked thereon is provided.

Also in the semiconductor device 1H including the InP-based HEMT having the Schottky gate structure, the resistance of the access region of a channel layer 22 between the gate electrode 30 and the source electrode 40 is reduced by providing the oxide film 60 between the gate electrode 30 and the source electrode 40. As a result, an increase in current and an increase in output of the semiconductor device 1H are achieved. Further, since the oxide film 60 is provided apart from the source electrode 40, the oxidation of the source electrode 40 due to the diffusion of O in the oxide film 60 is suppressed, and an increase in resistance of the source electrode 40 due to the oxidation is suppressed. Thus, the high-performance semiconductor device 1H is obtained.

Here, the semiconductor device 1H in which the oxide film 60 between the gate electrode 30 and the source electrode 40 is provided so as to be separated from the gate electrode 30 is illustrated. The oxide film 60 between the gate electrode 30 and the source electrode 40 may be provided so as to be in contact with the gate electrode 30 (a side surface 30a thereof), as in the example of the semiconductor device 1C (FIG. 5) described in the second embodiment.

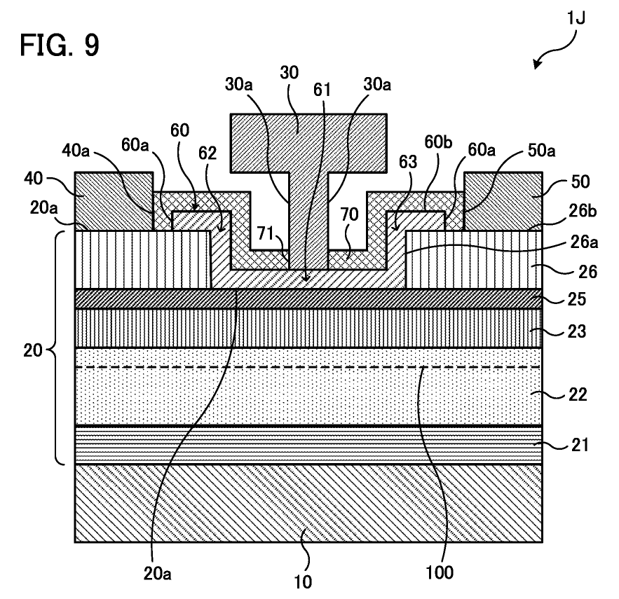

FIG. 9 is a diagram illustrating another example of the semiconductor device according to the fourth embodiment. FIG. 9 schematically illustrates a cross-sectional view of a main part of a third example of the semiconductor device according to the fourth embodiment.

A semiconductor device 1J illustrated in FIG. 9 is an example of a HEMT. The semiconductor device 1J is, for example, an InP-based HEMT.

In the semiconductor device 1J, a semiconductor layer 20 includes an etching stop layer 25 and a cap layer 26. The etching stop layer 25 is provided on a surface of the electron supply layer 23, the surface being opposite to the channel layer 22. For example, an InP-based semiconductor such as InP or InGaP (indium gallium phosphide) is used for the etching stop layer 25. The cap layer 26 is provided on a surface of the etching stop layer 25, the surface being opposite to the electron supply layer 23. The cap layer 26 includes, for example, an InP-based semiconductor such as InGaAs. The cap layer 26 has a recess 26a.

In the semiconductor device 1J, a gate electrode 30, a source electrode 40, a drain electrode 50, an oxide film 60, and nitride films 70 are provided on a surface 20a of the semiconductor layer 20 including the inner surface of the recess 26a. The source electrode 40 and the drain electrode 50 are provided on an upper surface 26b of the cap layer 26 on both sides of the recess 26a. The oxide film 60 is provided at least on the surface 20a of the semiconductor layer 20 in the recess 26a. The gate electrode 30 is provided on a first portion 61 of the oxide film 60 in the recess 26a. The gate electrode 30 has an MIS type gate structure. A second portion 62 of the oxide film 60 near the source electrode 40 and a third portion 63 of the oxide film 60 near the drain electrode 50 may be provided so as to extend from the inside of the recess 26a onto the upper surface 26b of the cap layer 26. The oxide film 60 (side surfaces 60a thereof) is provided apart from the source electrode 40 (a side surface 40a thereof) and the drain electrode 50 (a side surface 50a thereof) provided on the upper surface 26b of the cap layer 26. The nitride films 70 are provided to cover the oxide film 60 (the side surfaces 60a and an upper surface 60b thereof). Part of the nitride films 70 are provided between the second portion 62 of the oxide film 60 and the source electrode 40 and between the third portion 63 of the oxide film 60 and the drain electrode 50.

In the semiconductor device 1J of the InP-based HEMT, a 2DEG region 100 having a higher electron density than that below the recess 26a is generated below the cap layer 26 in a channel layer 22 of the semiconductor layer 20. In the semiconductor device 1J, by adjusting the width of the recess 26a, the electron density of the 2DEG region 100 below the recess 26a is adjusted to an electron density controllable by the electric field of the gate electrode 30 provided in the recess 26a.

In the semiconductor device 1J, the source electrode 40 is also referred to as a “first electrode”, the drain electrode 50 is also referred to as a “second electrode”, the first portion 61 of the oxide film 60 is also referred to as a “gate insulating film”, the second portion 62 is also referred to as a “first oxide film”, and the third portion 63 of the oxide film 60 is also referred to as a “second oxide film”. Alternatively, the drain electrode 50 is also referred to as a “first electrode”, the source electrode 40 is also referred to as a “second electrode”, the first portion 61 of the oxide film 60 is also referred to as a “gate insulating film”, the third portion 63 is also referred to as a “first oxide film”, and the second portion 62 is also referred to as a “second oxide film”.

The oxide film 60 as described above is used for the oxide film 60 of the semiconductor device 1J. That is, as the oxide film 60, for example, an oxide film having a single-layer structure such as an AlO film containing Al is provided. Alternatively, as the oxide film 60, an oxide film having a stacked structure including an oxide film such as an AlO film containing Al and an oxide film such as an HfO film containing Hf stacked thereon is provided.

In the semiconductor device 1J, the oxide film 60 is provided in the recess 26a between the gate electrode 30 and the source electrode 40 and between the gate electrode 30 and the drain electrode 50, thereby reducing the resistance of the access region of the channel layer 22. As a result, an increase in current and an increase in output of the semiconductor device 1J are achieved. Further, since the oxide film 60 is provided apart from the source electrode 40 and the drain electrode 50, the oxidation of the source electrode 40 and the drain electrode 50 due to the diffusion of O in the oxide film 60 is suppressed, and an increase in resistance of the source electrode 40 and the drain electrode 50 due to the oxidation is suppressed. Thus, the high-performance semiconductor device 1J is obtained.

The semiconductor device 1J may have a Schottky gate structure in which the gate electrode 30 penetrates the oxide film 60 and reaches the semiconductor layer 20. In this case, the oxide film 60 may be provided so as not to be in contact with the gate electrode 30, or may be provided so as to be in contact with the gate electrode 30.

As in the example of the semiconductor device 1G (FIG. 8A), the semiconductor device 1J may have a configuration in which the oxide film 60 is provided between the gate electrode 30 and the semiconductor layer 20 and between the gate electrode 30 and the source electrode 40, and is not provided between the gate electrode 30 and the drain electrode 50.

As in the example of the semiconductor device 1H (FIG. 8B), the semiconductor device 1J may have a configuration in which the oxide film 60 is provided between the gate electrode 30 and the source electrode 40 and is not provided between the gate electrode 30 and the semiconductor layer 20 and between the gate electrode 30 and the drain electrode 50. In this case, the oxide film 60 may be provided so as not to be in contact with the gate electrode 30, or may be provided so as to be in contact with the gate electrode 30.

In the semiconductor device 1J, the second portion 62 and the third portion 63 of the oxide film 60 do not necessarily have to be provided so as to extend from the inside of the recess 26a onto the upper surface 26b of the cap layer 26. The second portion 62 and the third portion 63 of the oxide film 60 may be provided on the surface 20a of the semiconductor layer 20 in the recess 26a and may be configured without being provided on the upper surface 26b of the cap layer 26.

In addition, although not illustrated here, in the case of the semiconductor device 1J of the InP-based HEMT, the semiconductor layer 20 may include an electron supply layer (referred to as a “lower electron supply layer” for convenience) provided between a buffer layer 21 and the channel layer 22. For example, InAlAs is used for the lower electron supply layer. The thickness of the lower electron supply layer is set in a range of, for example, about 2 nm to about 25 nm. For example, a predetermined region of the lower electron supply layer is doped with an impurity such as Si at a predetermined concentration. For example, the lower electron supply layer is formed by introducing an impurity, such as by delta doping (atomic layer doping). The impurity is doped in the form of a sheet at the interface between the buffer layer 21 and the lower electron supply layer. The doping interface has a depth of about 3 nm to 5 nm with respect to the surface of the lower electron supply layer. In this case, a portion of the lower electron supply layer closer to the surface than the doping interface may be regarded as the spacer layer.

In the case of the semiconductor device 1J of the InP-based HEMT, the semiconductor layer 20 may have a configuration in which the lower electron supply layer is provided between the buffer layer 21 and the channel layer 22 and the electron supply layer 23 is not provided between the channel layer 22 and the etching stop layer 25.

### FIFTH EMBODIMENT

Here, an example of a method of manufacturing the semiconductor device 1F (FIG. 7) having the GaN-based HEMT configuration as described in the third embodiment will be described as a fifth embodiment.

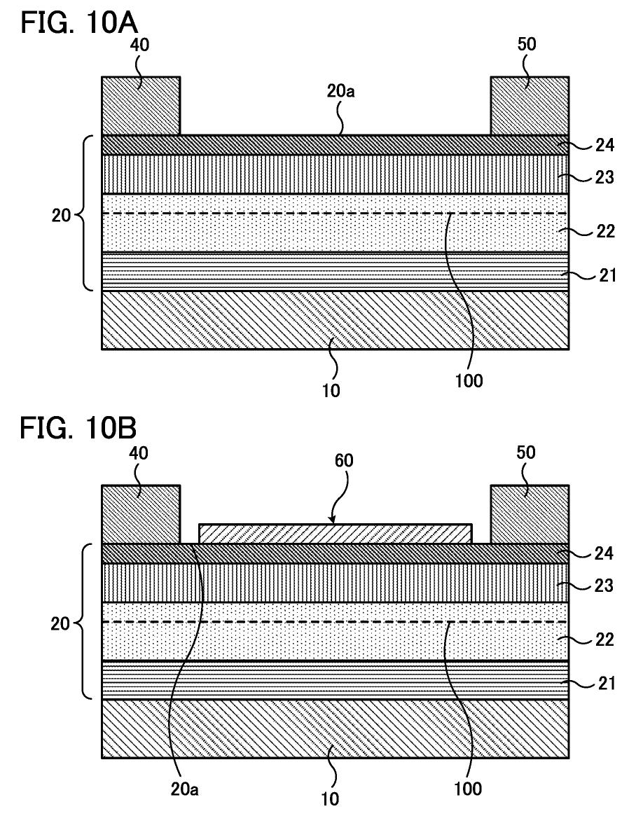

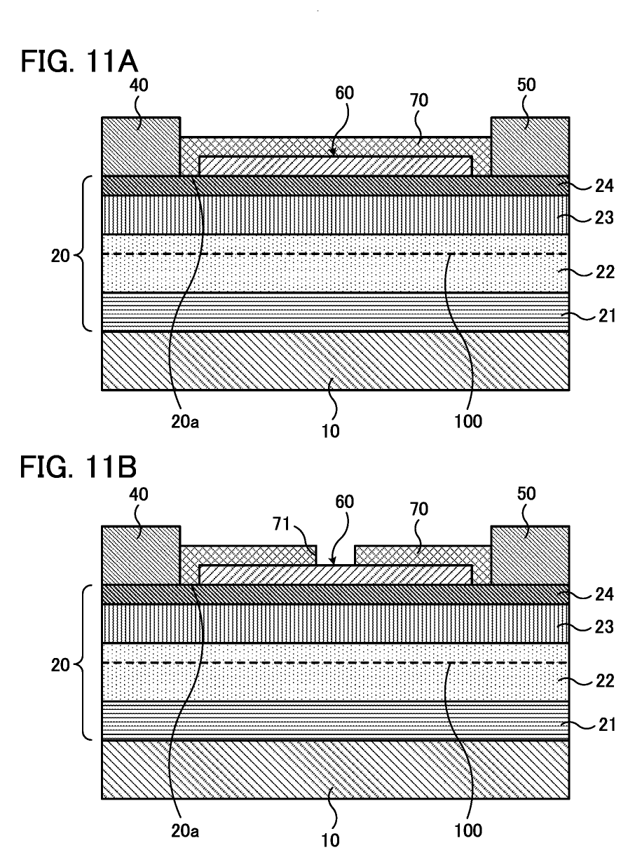

FIGS. 10A and 10B and FIGS. 11A and 11B illustrate an example of a semiconductor device manufacturing method according to the fifth embodiment. FIG. 10A schematically illustrates a cross-sectional view of a main part of an example of a semiconductor layer and an electrode forming process according to the fifth embodiment. FIG. 10B schematically illustrates a cross-sectional view of a main part of an example of an oxide film forming process according to the fifth embodiment. FIG. 11A schematically illustrates a cross-sectional view of a main part of an example of a nitride film forming process according to the fifth embodiment. FIG. 11B schematically illustrates a cross-sectional view of a main part of an example of an opening forming step according to the fifth embodiment.

First, as illustrated in FIG. 10A, a semiconductor layer 20 is formed on one surface of a substrate 10. As the substrate 10, for example, a substrate of SiC, GaN, AlN, or the like is used. A buffer layer 21, a channel layer 22, an electron supply layer 23, and a cap layer 24 of the semiconductor layer 20 are sequentially grown on the substrate 10 by MOCVD, for example. For example, the buffer layer 21 of AlN, the channel layer 22 of GaN, the electron supply layer 23 of AlGaN, and the cap layer 24 of GaN are sequentially grown. Each of the buffer layer 21, the channel layer 22, the electron supply layer 23, and the cap layer 24 is formed by growth of a predetermined compound semiconductor, to form the semiconductor layer 20. A 2DEG region 100 is generated in the channel layer 22 of the semiconductor layer 20.

After the semiconductor layer 20 is formed, an element isolation region (not illustrated) is formed as follows, for example. First, a resist mask (not illustrated) having an opening in the region where the element isolation region is to be formed is formed on the cap layer 24. Ion implantation of, for example, Ar (argon) or the like is performed using the resist mask as a mask, and an inactive region in which the 2DEG region 100 has disappeared is formed. Alternatively, dry etching using a chlorine-based gas is performed using the resist mask as a mask, and the cap layer 24, the electron supply layer 23, and the channel layer 22 are sequentially etched to form a trench. For example, an element isolation region (not illustrated) defining active regions is formed by the inactive region and the trench formed in this manner. After the element isolation region is formed, the resist mask is removed.

As illustrated in FIG. 10A, a source electrode 40 and a drain electrode 50 are formed on the semiconductor layer 20 in the active regions defined by the element isolation region. When the source electrode 40 and the drain electrode 50 are formed, a resist mask (not illustrated) having openings in the regions where the source electrode 40 and the drain electrode 50 are to be formed is formed on the cap layer 24. Following the formation of the resist mask, Ti and Al are sequentially formed by vapor deposition. Then, the resist mask is removed together with Ti and Al formed thereon. For example, the source electrode 40 and the drain electrode 50 are formed on the cap layer 24 using such a lift-off method.

After the source electrode 40 and the drain electrode 50 are formed, as illustrated in FIG. 10B, an oxide film 60 is formed on a surface 20a of the semiconductor layer 20.

To form the oxide film 60, first, the material of the oxide film 60 is formed so as to cover the semiconductor layer 20. At this point in time, the material of the oxide film 60 may be formed to cover the source electrode 40 and the drain electrode 50 in addition to the cap layer 24. As an example of the material of the oxide film 60, here, a stacked body of an AlO film and an HfO film thereon is formed. Such a material of the oxide film 60 may be formed to cover the semiconductor layer 20 by, for example, atomic layer deposition (ALD) method. The material of the oxide film 60 is preferably formed with a film thickness in the range of 1 nm to 10 nm. For example, after an AlO film having a film thickness of 2 nm is formed, an HfO film having a film thickness of 2 nm is formed thereon.

After the material of the oxide film 60 is formed, as illustrated in FIG. 10B, a portion of the material of the oxide film 60 formed, the portion being in contact with the source electrode 40 and the drain electrode 50, is selectively removed. At this time, for example, a resist mask (not illustrated) having openings in the regions corresponding to the source electrode 40, the drain electrode 50, and the peripheral portions thereof is formed using a photolithography technique. The material of the oxide film 60 covering the source electrode 40, the drain electrode 50, and the peripheral portions thereof is wet-etched by using this resist mask as a mask and by using alkaline solution such as tetramethylammonium hydroxide (TMAH), for example. As a result, the oxide film 60 as illustrated in FIG. 10B is formed so as to be separated from the source electrode 40 and the drain electrode 50.

After the oxide film 60 is formed, as illustrated in FIG. 11A, a nitride film 70 is formed so as to cover the oxide film 60. Part of the nitride film 70 is also formed between the oxide film 60 and the source electrode 40 and between the oxide film 60 and the drain electrode 50. The source electrode 40, the drain electrode 50, and the oxide film 60 are formed apart from each other. For example, an SiN film is formed as the nitride film 70. The nitride film 70 is formed using, for example, a plasma CVD method. Other than the plasma CVD method, an ALD method, a sputtering method, or the like may be used to form the nitride film 70. The film thickness of the nitride film 70 is set in the range of 2 nm to 500 nm, for example.

After the nitride film 70 is formed, as illustrated in FIG. 11B, an opening 71 is formed in a region of the nitride film 70 where a gate electrode 30 is to be formed. To form the opening 71, a resist mask (not illustrated) having an opening in the region where the opening 71 is to be formed is formed. Using this resist mask as a mask, dry etching using a fluorine-based gas is performed to form the opening 71 that leads to the oxide film 60.

After the formation of the nitride film 70 having the opening 71 leading to the oxide film 60, annealing is performed using water vapor at 350°C in order to reduce the impurities in the HfO contained in the oxide film 60. When the oxide film 60 does not include an oxide film containing Hf such as HfO, the annealing of the oxide film 60 may be omitted.

After the formation of the nitride film 70 having the opening 71 or after the annealing of the oxide film 60, the gate electrode 30 is formed as illustrated in FIG. 7. When the gate electrode 30 is formed, a resist mask (not illustrated) having an opening in a region where the gate electrode 30 is to be formed, that is, a region including the opening 71 of the nitride film 70, is formed on the nitride film 70. For example, an electron beam lithography technique is used to form the resist mask. As the resist mask, for example, a multilayer resist mask is formed. Following the formation of the resist mask, Ni and Au are sequentially formed by vapor deposition. Then, the resist mask is removed together with Ni and Au formed thereon. The gate electrode 30 is formed using such a lift-off method, for example. By forming the gate electrode 30, the semiconductor device 1F as illustrated in FIG. 7 is manufactured.

After the gate electrode 30 is formed, a passivation film, a wiring, and the like may be further formed.

Here, the case where the gate electrode 30 has the MIS type gate structure is described as an example. When the gate electrode 30 has a Schottky gate structure, after the opening 71 of the nitride film 70 is formed (FIG. 11B), the oxide film 60 exposed in the opening 71 is removed to form an opening that penetrates the oxide film 60 and reaches the semiconductor layer 20.

In the case where the oxide film 60 and the gate electrode 30 are not in contact with each other, or in the case where the oxide film 60 is not provided between the gate electrode 30 and the source electrode 40, when wet etching is performed after the material of the oxide film 60 is formed (FIG. 10B), a removal region of the material may be appropriately selected.

### SIXTH EMBODIMENT

Here, an example of a method of manufacturing the semiconductor device 1J (FIG. 9) having the InP-based HEMT configuration as described in the fourth embodiment will be described as a sixth embodiment.

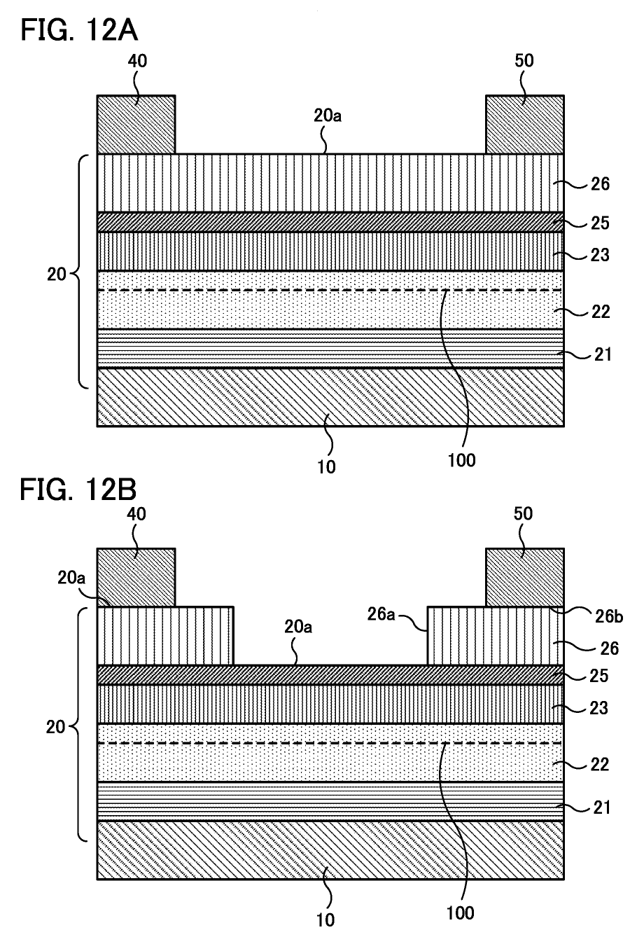

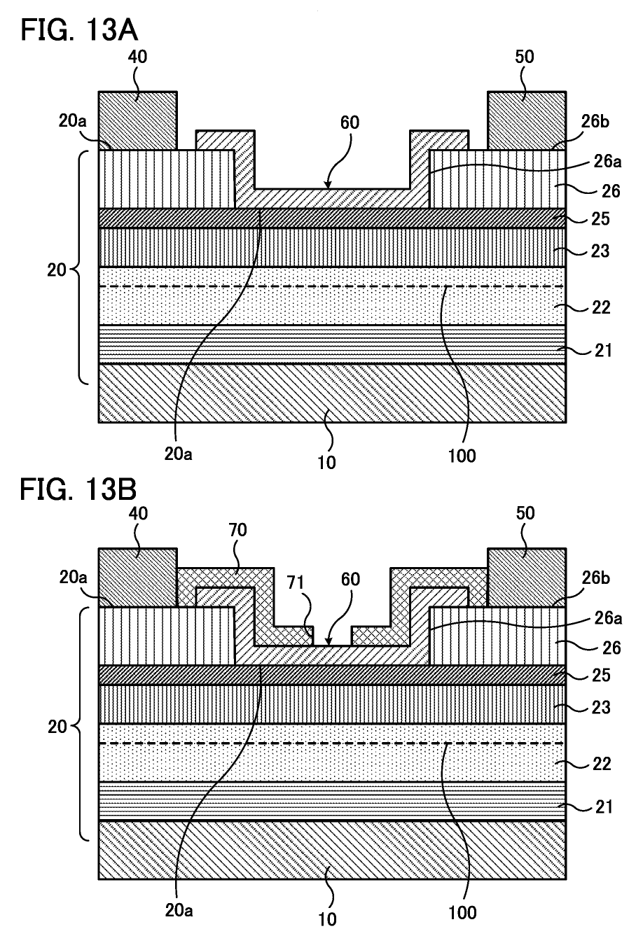

FIGS. 12A and 12B and FIGS. 13A and 13B illustrate an example of a semiconductor device manufacturing method according to the sixth embodiment. FIG. 12A schematically illustrates a cross-sectional view of a main part of an example of a semiconductor layer and an electrode forming process according to the sixth embodiment. FIG. 12B schematically illustrates a cross-sectional view of a main part of an example of the recess forming step according to the sixth embodiment. FIG. 13A schematically illustrates a cross-sectional view of a main part of an example of an oxide film forming process according to the sixth embodiment. FIG. 13B schematically illustrates a cross-sectional view of a main part of an example of a nitride film and an opening forming step according to the sixth embodiment.

First, as illustrated in FIG. 12A, a semiconductor layer 20 is formed on one surface of a substrate 10. For example, a substrate of InP or the like is used as the substrate 10. A buffer layer 21, a channel layer 22, an electron supply layer 23, an etching stop layer 25, and a cap layer 26 of the semiconductor layer 20 are sequentially grown on the substrate 10 by MOCVD, for example. For example, a buffer layer 21 of InAlAs, a channel layer 22 of InGaAs, an electron supply layer 23 of InAlAs, an etching stop layer 25 of InP or InGaP, and a cap layer 26 of InGaAs are sequentially grown. Each of the buffer layer 21, the channel layer 22, the electron supply layer 23, the etching stop layer 25, and the cap layer 26 is formed by growth of a predetermined compound semiconductor to form the semiconductor layer 20. A 2DEG region 100 is generated in the channel layer 22 of the semiconductor layer 20.

After the semiconductor layer 20 is formed, an element isolation region (not illustrated) is formed as follows, for example. First, a resist mask (not illustrated) having an opening in a region where an element isolation region is to be formed is formed on the cap layer 26. The cap layer 26 is etched using this resist mask as a mask and using a mixed solution of phosphoric acid and hydrogen peroxide water, for example. This etching is stopped at the etching stop layer 25. Next, for example, hydrochloric acid is used to etch the etching stop layer 25. This etching is stopped at the electron supply layer 23. Thereafter, the electron supply layer 23 and the channel layer 22 are etched using a mixed solution of phosphoric acid and hydrogen peroxide water, for example. For example, an element isolation region (not illustrated) defining active regions is formed by the trench thus formed. After the element isolation region is formed, the resist mask is removed.

As illustrated in FIG. 12A, a source electrode 40 and a drain electrode 50 are formed on the semiconductor layer 20 in the active regions defined by the element isolation region. When the source electrode 40 and the drain electrode 50 are formed, a resist mask (not illustrated) having openings in the regions where the source electrode 40 and the drain electrode 50 are to be formed is formed on the cap layer 26. Following the formation of the resist mask, Ti, Pt, and Au are sequentially formed by vapor deposition. Then, the resist mask is removed together with Ti, Pt and Au formed thereon. For example, the source electrode 40 and the drain electrode 50 are formed on the cap layer 26 using such a lift-off method.

After the source electrode 40 and the drain electrode 50 are formed, as illustrated in FIG. 12B, a recess 26a is formed in the cap layer 26. The recess 26a is formed in a region of the cap layer 26 between the source electrode 40 and the drain electrode 50. When the recess 26a is formed, a resist mask (not illustrated) having an opening in the region where the recess 26a is to be formed is formed on the cap layer 26. For example, an electron beam lithography technique is used to form the resist mask. The cap layer 26 is etched using the formed resist mask as a mask and using a mixed solution of phosphoric acid and hydrogen peroxide water, for example. This etching is stopped at the etching stop layer 25. By using such a method, the recess 26a is formed in the cap layer 26. By adjusting the width of the recess 26a, the electron density of the 2DEG region 100 generated in the channel layer 22 below the recess 26a is adjusted.

After the recess 26a of the cap layer 26 is formed, as illustrated in FIG. 13A, an oxide film 60 is formed on a surface 20a of the semiconductor layer 20.

To form the oxide film 60, first, the material of the oxide film 60 is formed so as to cover the semiconductor layer 20. At this point in time, the material of the oxide film 60 is formed to cover the inside of the recess 26a and an upper surface 26b of the cap layer 26, and may be formed to cover the source electrode 40 and the drain electrode 50. As an example of the material of the oxide film 60, here, a stacked body of an AlO film and an HfO film thereon is formed. Such a material of the oxide film 60 is formed so as to cover the semiconductor layer 20 using an ALD method, for example. The material of the oxide film 60 is preferably formed with a film thickness in the range of 1 nm to 10 nm. For example, after an AlO film having a film thickness of 2 nm is formed, an HfO film having a film thickness of 2 nm is formed thereon.

After the material of the oxide film 60 is formed, as illustrated in FIG. 13A, portions of the material of the oxide film 60, the portions being formed in contact with the source electrode 40 and the drain electrode 50, are selectively removed. At this time, a resist mask (not illustrated) having openings in the regions corresponding to the source electrode 40, the drain electrode 50, and the peripheral portions thereof is formed using a photolithography technique, for example. The material of the oxide film 60 covering the source electrode 40, the drain electrode 50, and the peripheral portions thereof is wet-etched using the resist mask as a mask and using, for example, an alkaline solution such as TMAH. As a result, the oxide film 60 as illustrated in FIG. 13A is formed so as to be separated from the source electrode 40 and the drain electrode 50.

After the oxide film 60 is formed, as illustrated in FIG. 13B, a nitride film 70 is formed so as to cover the oxide film 60. Part of the nitride film 70 is also formed between the oxide film 60 and the source electrode 40 and between the oxide film 60 and the drain electrode 50. The source electrode 40, the drain electrode 50, and the oxide film 60 are formed apart from each other. For example, an SiN film is formed as the nitride film 70. The nitride film 70 is formed using a plasma CVD method, for example. Other than the plasma CVD method, an ALD method, a sputtering method, or the like may be used to form the nitride film 70. The film thickness of the nitride film 70 is set in the range of 2 nm to 500 nm, for example.

After the nitride film 70 is formed, as illustrated in FIG. 13B, an opening 71 is formed in a region of the nitride film 70 where the gate electrode 30 is to be formed. To form the opening 71, a resist mask (not illustrated) having an opening in the region where the opening 71 is to be formed is formed. Using this resist mask as a mask, dry etching using a fluorine-based gas is performed to form the opening 71 that leads to the oxide film 60.

After the nitride film 70 having the opening 71 leading to the oxide film 60 is formed, annealing is performed using water vapor at 350°C in order to reduce the impurities in the HfO contained in the oxide film 60. When the oxide film 60 does not include an oxide film containing Hf such as HfO, the annealing of the oxide film 60 may be omitted.

After the formation of the nitride film 70 having the opening 71 or after the annealing of the oxide film 60, the gate electrode 30 is formed as illustrated in FIG. 9. When the gate electrode 30 is formed, a resist mask (not illustrated) having an opening in the region where the gate electrode 30 is to be formed, that is, a region including the opening 71 of the nitride film 70, is formed on the nitride film 70. For example, an electron beam lithography technique is used to form the resist mask. As the resist mask, for example, a multilayer resist mask is formed. Following the formation of the resist mask, Ti, Pt, and Au are sequentially formed by vapor deposition. Then, the resist mask is removed together with Ti, Pt and Au formed thereon. For example, the gate electrode 30 is formed using such a lift-off method. By forming the gate electrode 30, the semiconductor device 1J as illustrated in FIG. 9 is manufactured.

After the gate electrode 30 is formed, a passivation film, a wiring, and the like may be further formed.

Here, an example in which InP is used as the substrate 10 of the semiconductor device 1J is illustrated. However, the substrate 10 is not limited to InP, and various substrates may be used. For example, a substrate of GaAs or the like may be used as the substrate 10. The material and structure of the buffer layer 21 formed between the substrate 10 and the channel layer 22 are appropriately adjusted based on the type of the substrate 10 to be used. That is, the buffer layer 21 on which the channel layer 22 is growable is formed on the substrate 10.

In this embodiment, a case in which the gate electrode 30 has an MIS gate structure has been described as an example. When the gate electrode 30 has a Schottky gate structure, after the opening 71 of the nitride film 70 is formed (FIG. 13B), the oxide film 60 exposed in the opening 71 may be removed to form an opening penetrating the oxide film 60 and reaching the semiconductor layer 20.

When the oxide film 60 and the gate electrode 30 are formed to be not in contact with each other or when the oxide film 60 is not provided between the gate electrode 30 and the drain electrode 50, the wet etching may be modified. For example, when wet etching is performed after the material of the oxide film 60 is formed (FIG. 13A), the removal area of the material may be appropriately selected.

A lower electron supply layer may be provided between the buffer layer 21 and the channel layer 22. When the lower electron supply layer is provided between the buffer layer 21 and the channel layer 22, the electron supply layer 23 between the channel layer 22 and the etching stop layer 25 may be omitted.

As described above, in the semiconductor devices 1A, 1B, 1C, 1D, 1E, 1F, 1G, 1H, 1J, and the like described in the first to sixth embodiments, the gate electrode 30 may be disposed closer to the source electrode 40 than the drain electrode 50, that is, may be disposed asymmetrically in order to increase the breakdown voltage.

In the above description, the HEMT is used as an example. However, the technique described above, that is, the technique of separating the oxide film provided on the surface of the semiconductor layer from the source electrode or the drain electrode, is not limited to the HEMT, and it may be applied to a semiconductor device including various transistors. For example, the above technique may be applied to a semiconductor device including a MIS transistor using a semiconductor such as Si, a power semiconductor device using a compound semiconductor such as SiC, and the like. The above technique may be applied to various semiconductor devices including a bipolar transistor, an insulated gate bipolar transistor, and the like, other than a field effect transistor.

The semiconductor devices 1A, 1B, 1C, 1D, 1E, 1F, 1G, 1H, 1J, and the like (also referred to as “1A-1H, 1J, and the like”) described above may be applied to various electronic apparatuses. As examples, cases where a semiconductor device having the above-described configuration is applied to a semiconductor package, a power factor correction circuit, a power supply device, and an amplifier will be described below.

### SEVENTH EMBODIMENT

Here, an example of application of a semiconductor device having the above-described configuration to a semiconductor package will be described as a seventh embodiment.

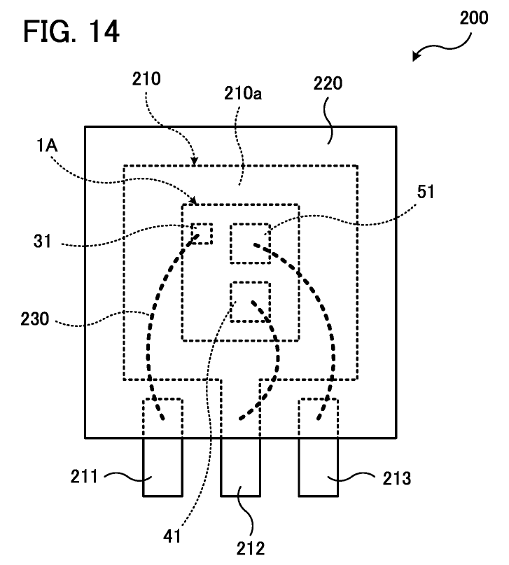

FIG. 14 is a diagram illustrating an example of a semiconductor package according to a seventh embodiment. FIG. 14 schematically illustrates a plan view of a main part of an example of a semiconductor package.

A semiconductor package 200 illustrated in FIG. 14 is an example of a discrete package. The semiconductor package 200 includes, for example, the semiconductor device 1A (FIG. 1) described in the first embodiment, a lead frame 210 on which the semiconductor device 1A is mounted, and a resin 220 that seals them.

The semiconductor device 1A is mounted on, for example, a die pad 210a of the lead frame 210 using a die attach material or the like (not illustrated). The semiconductor device 1A is provided with a pad 31 connected to the gate electrode 30, a pad 41 connected to the source electrode 40, and a pad 51 connected to the drain electrode 50. The pad 31, the pad 41, and the pad 51 are respectively connected to a gate lead 211, a source lead 212, and a drain lead 213 of the lead frame 210 using wires 230 made of Au, Al, or the like. The lead frame 210, the semiconductor device 1A mounted thereon, and the wires 230 connecting them are sealed with the resin 220 so that the gate lead 211, the source lead 212, and the drain lead 213 are partially exposed.

An external connection electrode connected to the source electrode 40 may be provided on a surface of the semiconductor device 1A, the surface being opposite to the surface on which the pad 31 connected to the gate electrode 30 and the pad 51 connected to the drain electrode 50 are provided. The external connection electrode may be connected to the die pad 210a connected to the source lead 212 using a conductive bonding material such as solder.

The semiconductor package 200 having such a configuration is obtained by using the semiconductor device 1A described in the first embodiment, for example.

As described above, in the semiconductor device 1A, the oxide film 60 is provided between the gate electrode 30 and at least one of the source electrode 40 and the drain electrode 50 on the surface 20a of the semiconductor layer 20, and the oxide film 60 is provided apart from the electrode. By providing the oxide film 60, the resistance of the access region is reduced, and a large current and a high output are achieved. Further, since the oxide film 60 is provided apart from the electrode, an increase in resistance due to the oxidation of the electrode caused by O in the oxide film 60 is suppressed. Thus, the high-performance semiconductor device 1A is obtained. By using the semiconductor device 1A, the high-performance semiconductor package 200 is obtained.

Here, although the semiconductor device 1A is used as an example, it is possible to obtain semiconductor packages by using other semiconductor devices 1B-1H, 1J, and the like.

### EIGHTH EMBODIMENT

Here, an example of application of a semiconductor device having the above configuration to a power factor correction circuit will be described as an eighth embodiment.

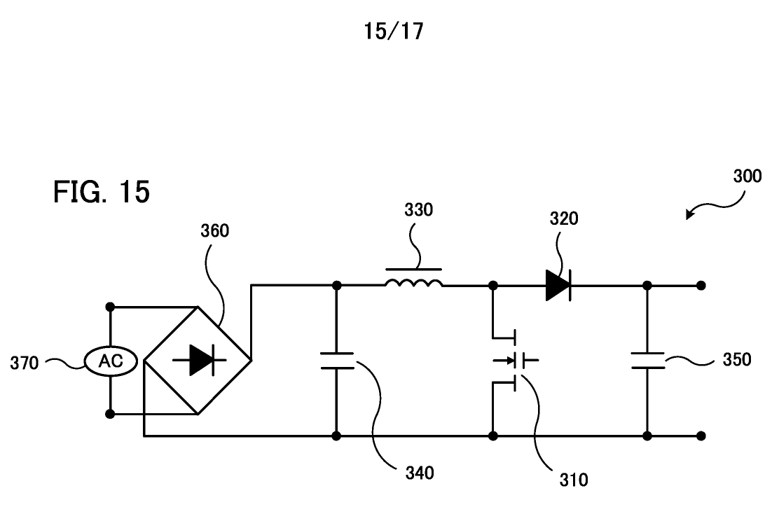

FIG. 15 is a diagram illustrating an example of a power factor correction circuit according to an eighth embodiment. FIG. 15 illustrates an equivalent circuit diagram of an example of the power factor correction circuit.

A power factor correction (PFC) circuit 300 illustrated in FIG. 15 includes a switching element 310, a diode 320, a choke coil 330, a capacitor 340, a capacitor 350, a diode bridge 360, and an AC power supply 370 (AC).

In the PFC circuit 300, the drain electrode of the switching element 310 is connected to the anode terminal of the diode 320 and one terminal of the choke coil 330. The source electrode of the switching element 310 is connected to one terminal of the capacitor 340 and one terminal of the capacitor 350. The other terminal of the capacitor 340 and the other terminal of the choke coil 330 are connected to each other. The other terminal of the capacitor 350 and the cathode terminal of the diode 320 are connected to each other. A gate driver is connected to the gate electrode of the switching element 310. The AC power supply 370 is connected between both terminals of the capacitor 340 via the diode bridge 360, and a DC power supply (DC) is obtained from between both terminals of the capacitor 350.

For example, any one of the semiconductor devices 1A to 1H, 1J, and the like may be used for the switching element 310 of the PFC circuit 300 having the above-described configuration.

As described above, in the semiconductor devices 1A to 1H, 1J, and the like, the oxide film 60 is provided between the gate electrode 30 and at least one of the source electrode 40 and the drain electrode 50 on the surface 20a of the semiconductor layer 20, and the oxide film 60 is provided apart from the electrode. By providing the oxide film 60, the resistance of the access region is reduced, and a large current and a high output are achieved. Further, since the oxide film 60 is provided apart from the electrode, an increase in resistance due to the oxidation of the electrode caused by O in the oxide film 60 is suppressed. Thus, the high-performance semiconductor devices 1A to 1H, 1J, and the like are obtained. The high-performance PFC circuit 300 is obtained by using any one of the semiconductor devices 1A to 1H, 1J, and the like.

### NINTH EMBODIMENT

Here, an application example of a semiconductor device having the above configuration to a power supply device will be described as a ninth embodiment.

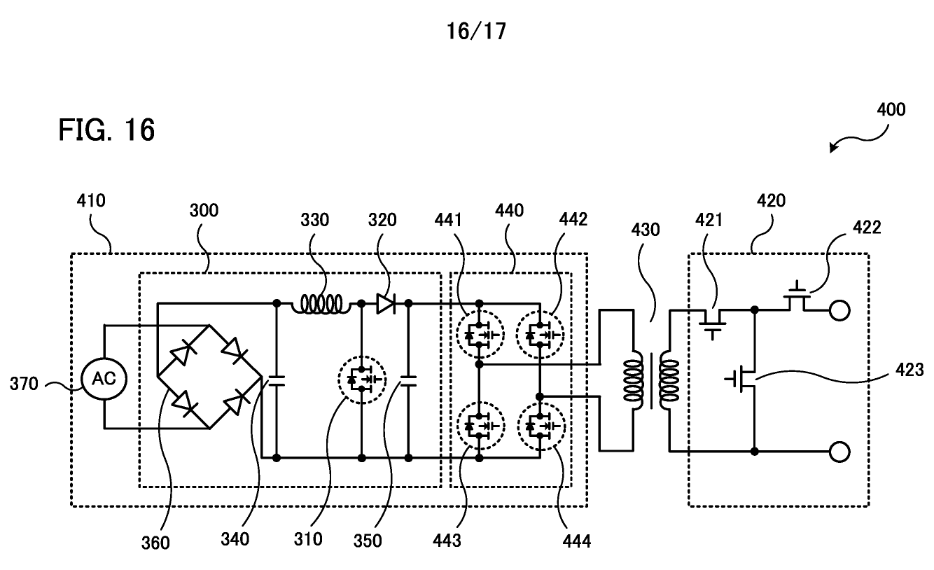

FIG. 16 is a diagram illustrating an example of a power supply device according to a ninth embodiment. FIG. 16 illustrates an equivalent circuit diagram of an example of the power supply device.

A power supply device 400 illustrated in FIG. 16 includes a primary circuit 410, a secondary circuit 420, and a transformer 430 provided between the primary circuit 410 and the secondary circuit 420.

The primary circuit 410 includes the PFC circuit 300 as described in the eighth embodiment and an inverter circuit, for example, a full-bridge inverter circuit 440 connected between both terminals of the capacitor 350 of the PFC circuit 300. The full-bridge inverter circuit 440 includes a plurality of, for example, four switching elements 441, 442, 443, and 444.

The secondary circuit 420 includes a plurality of, for example, three switching elements 421, 422, and 423.

For example, the semiconductor devices 1A to 1H, 1J, and the like are used for the switching element 310 of the PFC circuit 300 included in the primary circuit 410 and for the switching elements 441 to 444 of the full-bridge inverter circuit 440 of the power supply device 400 having the above-described configuration. For example, as the switching elements 421, 422, and 423 of the secondary circuit 420 of the power supply device 400, normal MIS field-effect transistors using Si are used.

As described above, in the semiconductor devices 1A to 1H, 1J, and the like, the oxide film 60 is provided between the gate electrode 30 and at least one of the source electrode 40 and the drain electrode 50 on the surface 20a of the semiconductor layer 20, and the oxide film 60 is provided apart from the electrode. By providing the oxide film 60, the resistance of the access region is reduced, and a large current and a high output are achieved. Further, since the oxide film 60 is provided apart from the electrode, an increase in resistance due to the oxidation of the electrode caused by O in the oxide film 60 is suppressed. Thus, the high-performance semiconductor devices 1A to 1H, 1J, and the like are obtained. By using the semiconductor devices 1A to 1H, 1J, and the like, the high-performance power supply device 400 is obtained.

### TENTH EMBODIMENT

Here, an example of application of a semiconductor device having the above-described configuration to an amplifier will be described as a tenth embodiment.

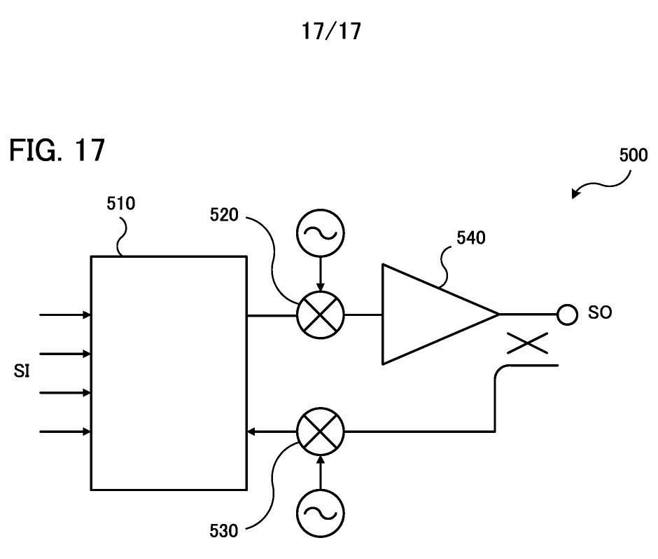

FIG. 17 is a diagram illustrating an example of an amplifier according to a tenth embodiment. FIG. 17 illustrates an equivalent circuit diagram of an example of the amplifier.

An amplifier 500 illustrated in FIG. 17 includes a digital predistortion circuit 510, a mixer 520, a mixer 530, and a power amplifier 540.

The digital predistortion circuit 510 compensates for nonlinear distortion of an input signal. The mixer 520 mixes this input signal SI whose nonlinear distortion has been compensated with an AC signal. The power amplifier 540 amplifies a signal obtained by mixing the input signal SI with the AC signal. In the amplifier 500, for example, by switching a switch, an output signal SO is mixed with an AC signal by the mixer 530 and is sent to the digital predistortion circuit 510. The amplifier 500 may be used as a high-frequency amplifier or a high-power amplifier.

Any one of the semiconductor devices 1A to 1H, 1J, and the like may be used for the power amplifier 540 of the amplifier 500 having the above-described configuration.

As described above, in the semiconductor devices 1A to 1H, 1J, and the like, the oxide film 60 is provided between the gate electrode 30 and at least one of the source electrode 40 and the drain electrode 50 on the surface 20a of the semiconductor layer 20, and the oxide film 60 is provided apart from the electrode. By providing the oxide film 60, the resistance of the access region is reduced, and a large current and a high output are achieved. Further, since the oxide film 60 is provided apart from the electrode, an increase in resistance due to the oxidation of the electrode caused by O in the oxide film 60 is suppressed. Thus, the high-performance semiconductor devices 1A to 1H, 1J, and the like are obtained. The high-performance amplifier 500 is obtained by using any one of the semiconductor devices 1A to 1H, 1J, and the like.

Various electronic devices (the semiconductor package 200, the PFC circuit 300, the power supply device 400, the amplifier 500, and the like described in the seventh to tenth embodiments) to which the semiconductor devices 1A to 1H, 1J, and the like are applied may be mounted on various electronic apparatuses or electronic equipment. For example, these electronic devices may be mounted on various electronic equipment or electronic apparatuses such as a computer (a personal computer, a supercomputer, a server, or the like), a smartphone, a mobile phone, a tablet terminal, a sensor, a camera, an audio device, a measurement device, an inspection device, a manufacturing device, a transmitter, a receiver, and a radar device.

In one aspect, it is possible to obtain a high-performance semiconductor device in which oxidation of an electrode is suppressed.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor device comprising:
a semiconductor layer;
a gate electrode provided on a first surface of the semiconductor layer;
a first electrode provided on the first surface of the semiconductor layer and separated from the gate electrode; and
a first oxide film provided between the gate electrode and the first electrode on the first surface of the semiconductor layer and apart from the first electrode.

2. The semiconductor device according to claim 1,
wherein the semiconductor layer includes
a channel layer including a first compound semiconductor, and
an electron supply layer stacked on the channel layer and including a second compound semiconductor different from the first compound semiconductor.

3. The semiconductor device according to claim 1, further comprising:
a gate insulating film provided between the first surface of the semiconductor layer and the gate electrode,
wherein the first oxide film is provided continuously with the gate insulating film.

4. The semiconductor device according to claim 1, wherein the first oxide film is provided apart from the gate electrode.

5. The semiconductor device according to claim 1, wherein the first oxide film contains aluminum.

6. The semiconductor device according to claim 1, wherein the first oxide film includes
a first layer including an oxide film containing aluminum, and
a second layer stacked on the first layer and including an oxide film containing hafnium.

7. The semiconductor device according to claim 6, wherein the second layer further contains aluminum or silicon.

8. The semiconductor device according to claim 1, wherein the first oxide film is amorphous.

9. The semiconductor device according to claim 1, further comprising:
a first nitride film provided between the first electrode and the first oxide film on the first surface of the semiconductor layer.

10. The semiconductor device according to claim 9, wherein the first nitride film contains silicon.

11. The semiconductor device according to claim 1, further comprising:
a second electrode provided so as to be separated from the gate electrode and the first electrode on a portion of the first surface of the semiconductor layer, the portion being opposite to a first electrode side of the gate electrode, and
a second oxide film provided between the gate electrode and the second electrode on the first surface of the semiconductor layer and apart from the second electrode.

12. The semiconductor device according to claim 11, further comprising:
a gate insulating film provided between the first surface of the semiconductor layer and the gate electrode,
wherein the second oxide film is provided continuously with the gate insulating film.

13. The semiconductor device according to claim 11, wherein the first oxide film and the second oxide film are provided apart from the gate electrode.

14. The semiconductor device according to claim 11, further comprising:
a second nitride film provided between the second electrode and the second oxide film on the first surface of the semiconductor layer.

15. A semiconductor device manufacturing method, comprising:
forming a gate electrode on a first surface of a semiconductor layer;
forming a first electrode on the first surface of the semiconductor layer such that the first electrode is separated from the gate electrode; and
forming a first oxide film on the first surface of the semiconductor layer between the gate electrode and the first electrode such that the first oxide film is spaced apart from the first electrode.

16. The semiconductor device manufacturing method according to claim 15, further comprising:
forming, after forming the first electrode on the first surface of the semiconductor layer, the first oxide film such that the first oxide film is provided apart from the first electrode; and
forming, after forming the first oxide film, the gate electrode on the first surface of the semiconductor layer such that the gate electrode is separated from the first electrode and such that the first oxide film is provided between the gate electrode and the first electrode.

17. The semiconductor device manufacturing method according to claim 15, further comprising:
forming a first nitride film on the first surface of the semiconductor layer between the first electrode and the first oxide film.

18. The semiconductor device manufacturing method according to claim 15, further comprising:
forming a second electrode provided so as to be separated from the gate electrode and the first electrode on a portion of the first surface of the semiconductor layer, the portion being opposite to a first electrode side of the gate electrode, and
forming a second oxide film provided between the gate electrode and the second electrode on the first surface of the semiconductor layer and apart from the second electrode.

19. The semiconductor device manufacturing method according to claim 18, further comprising:
forming, after forming the first electrode and the second electrode on the first surface of the semiconductor layer, the first oxide film such that the first oxide film is provided apart from the first electrode and the second oxide film such that the second oxide film is provided apart from the second electrode;
forming, after the first oxide film and the second oxide film are formed, the gate electrode between the first electrode and the second electrode on the first surface of the semiconductor layer such that the gate electrode is separated from the first electrode and the second electrode, such that the first oxide film is provided between the gate electrode and the first electrode, and such that the second oxide film is provided between the gate electrode and the second electrode.

20. An electronic apparatus comprising:
a semiconductor device including
a semiconductor layer,
a gate electrode provided on a first surface of the semiconductor layer,
a first electrode provided on the first surface of the semiconductor layer and separated from the gate electrode, and
a first oxide film provided between the gate electrode and the first electrode on the first surface of the semiconductor layer and apart from the first electrode.
